(19) United States
(12) Patent Application Publication
(10) Pub. No.: US 2015/0249069 A1
(43) Pub. Date: Sep. 3, 2015

(54) DISPLAY DEVICE AND METHOD FOR MANUFACTURING DISPLAY DEVICE

(71) Applicant: Sharp Kabushiki Kaisha, Osaka (JP)

(72) Inventors: Hidefumi Yoshida, Osaka (JP); Takayuki Nishiyama, Osaka (JP)

(73) Assignee: Sharp Kabushiki Kaisha, Osaka (JP)

(21) Appl. No.: 14/429,536

(22) PCT Filed: Sep. 25, 2013
(86) PCT No.: PCT/JP2013/075882

§ 371 Date: Mar. 19, 2015

(30) Foreign Application Priority Data
Sep. 25, 2012 (JP) 2012-211494
Oct. 5, 2012 (JP) 2012-223379

(51) Int. Cl. H01L 25/075; H01L 33/50; H01L 33/38; H01L 33/62; H01L 33/58

(52) U.S. Cl. CPC H01L 25/0753; H01L 33/62; H01L 33/58; H01L 33/387; H01L 33/505; H01L 2933/0016; H01L 2933/0058; H01L 2933/0066

(57) ABSTRACT

Provided is a low cost and high resolution display device having light-emitting elements. An LED element is provided in a region between a first substrate and a second substrate, the region being an intersection region where a first electrode and a second electrode intersect each other in a plan view, and the LED element is provided with a first element electrode connected to the first electrode and provided on a bottom surface, and a second element electrode connected to a second electrode and provided on a top surface.

### TECHNICAL FIELD

The present invention relates to a display device including light-emitting elements and to a method of manufacturing a display device.

### BACKGROUND ART

LED displays, which are light-emitting displays, have garnered attention as display devices that have low power consumption and reproduce a wide range of colors.

LED displays are display devices in which a large number of LED elements, which are light-emitting elements, are arranged in a matrix on a substrate, and have excellent performance in areas such as high contrast, wide color range, and low power consumption compared to conventional liquid crystal display devices and the like.

Also, in recent years, 55 inch FHD LED displays have been shown at expositions and the like.

Patent Document 1 discloses an image display device having light-emitting elements such as light-emitting diodes arranged on a substrate.

FIG. 41 is a plan view showing the configuration of an image display device disclosed in Patent Document 1 as a conventional technique. The LED display shown in FIG. 41 is of a so-called simple matrix type.

The image display device 400 shown in FIG. 41 has lower wiring lines 402 and transparent electrodes 403R, 403G, and 403B formed on a substrate 401, and on the upper surface thereof, light-emitting elements 405R, 405G, and 405B and an insulating layer are formed. Also, upper wiring lines 404R, 404G, and 404B and connecting electrodes 406R, 406G, and 406B integrally formed respectively with the upper wiring lines 404R, 404G, and 404B are formed on the upper surface. The light-emitting surface of the light-emitting elements 405R, 405G, and 405B are electrically connected respectively to the transparent electrodes 403R, 403G, and 403B, and the portions of the light-emitting elements opposite to the light-emitting surfaces are electrically connected respectively to the connecting electrodes 406R, 406G, and 406B. As light-emitting elements 405R, 405G, and 405B, light-emitting diodes (LEDs) are used.

In such LED displays, images are displayed by sequentially scanning electrodes, which apply voltage.

However, due to the high price of LED displays, commercial viability has been an issue.

One reason for the high price of LED displays is the high price of parts. That is, in order to attain an FHD LED display, 6 million LED elements must be disposed on a substrate. Currently, each LED element costs approximately 1 JPY, which means that the LED elements alone would cost 6 million JPY, resulting in the price being approximately 30 times that of conventional display devices.

Another reason for the high price of LED displays is the high manufacturing cost. That is, in the process of manufacturing an LED display, a high degree of accuracy is necessary in arranging the LED elements. In conventional liquid crystal display devices or organic EL display devices, the substrates are given surface treatment to form the pixels in a uniform manner, but in LED displays, pixels are formed by disposing individual elements on the substrate. Thus, a high degree of positional accuracy is required in order to mount the LED elements on the substrate, which necessarily results in a higher manufacturing cost.

Conventionally, LED elements have been arranged on the substrate using robots, for example, but with this method, the positional accuracy is bad and the productive efficiency is low.

Patent Document 2 discloses a method of arranging elements in which light-emitting elements are arranged on a substrate having recesses by inserting light-emitting elements in a fluid and moving the light-emitting elements in the fluid.

Patent Document 3 discloses a method of transferring elements from one substrate on which they are arranged to another substrate, in order to arrange light-emitting elements on a substrate of a display device.

### RELATED ART DOCUMENTS

### Patent Documents

Patent Document 1: Japanese Patent Application Laid-Open Publication, “Japanese Patent Application Laid-Open Publication No. 2006-65011 (Published on Mar. 9, 2006)”

Patent Document 2: Japanese Patent Application Laid-Open Publication, “Japanese Patent Application Laid-Open Publication No. 2005-209772 (Published on Aug. 4, 2005)”

Patent Document 3: Japanese Patent Application Laid-Open Publication, “Japanese Patent Application Laid-Open Publication No. 2004-273596 (Published on Sep. 30, 2004)”

### SUMMARY OF THE INVENTION

### Problems to be Solved by the Invention

However, in the process of manufacturing an LED display, when the method of arranging elements of Patent Document 2 is used as the method of arranging elements on a substrate of a display device, a low number of elements can be arranged per unit time, and thus, the production efficiency is low.

In the element transfer method of Patent Document 3, elements are transferred per emitted color thereof, for example, and thus, time is required in order to transfer the elements. Also, in order to electrically connect the elements to the electrodes, a high degree of accuracy is required in positioning the elements with respect to the electrodes, and thus, it is not possible to simplify the manufacturing process, which means that production cost cannot be reduced.

Also, in the image display device 400 of Patent Document 1, the light-emitting elements 405R, 405G, and 405B are electrically connected to the connecting electrodes 406R, 406G, and 406B, which branch off from the upper wiring lines 404R, 404G, and 404B, and transparent electrodes 403R, 403G, and 403B, which branch off from the lower wiring lines 402.

The connecting electrodes 406R, 406G, and 406B branch off in a direction perpendicular to the extension direction of the upper wiring lines 404R, 404G, and 404B, and the transparent electrodes 403R, 403G, and 403B branch off in a direction perpendicular to the extension direction of the lower wiring lines 402.

Thus, when arranging the light-emitting elements 405R, 405G, and 405B on a display surface of a given area, an amount of area corresponding to the lengths of the connecting electrodes 406R, 406G, and 406B and the transparent electrodes 403R, 403G, and 403B is lost, which results in an inability to attain a high resolution. Also, the light-emitting elements 405R, 405G, and 405B need to be arranged to be electrically connected to the connecting electrodes 406R, 406G, and 406B and the transparent electrodes 403R, 403G, and 403B, and a high degree of positioning accuracy is required in order to arrange the light-emitting elements 405R, 405G, and 405B.

The present invention was made in view of the above-mentioned problems, and an object thereof is to provide a low cost and high resolution display device having light-emitting elements, and a manufacturing method by which it is possible to manufacture this display device at a high efficiency and low cost.

### Means for Solving the Problems

In order to solve the above-mentioned problems, the display device of an aspect of the present invention, includes: a first substrate including a plurality of first electrodes; a second substrate including a plurality of second electrodes disposed to face the first substrate; and light-emitting elements that emit light by a voltage applied thereto, wherein the first electrodes and the second electrodes are arranged in stripe patterns such that the first electrodes extend in a direction differing from a direction in which the second electrodes extend, wherein the light-emitting elements are provided in areas between the first substrate and the second substrate in intersecting regions, the intersecting regions being regions where the first electrodes and the second electrodes intersect in a plan view, and wherein each of the light-emitting elements includes a first element electrode provided in a bottom surface of the light-emitting element and electrically connected to the first electrode, and a second element electrode provided in a top surface of the light-emitting element and electrically connected to the second electrode.

In order to solve the above-mentioned problems, a method of manufacturing a display device of an aspect of the present invention is a method of manufacturing a display device that includes a first substrate having a plurality of first electrodes; a second substrate having a plurality of second electrodes disposed to face the first substrate; and a plurality of light-emitting elements that each emit light by a voltage applied thereto, wherein the first electrodes and the second electrodes are respectively arranged in stripe patterns such that the first electrodes extend in a direction differing from a direction in which the second electrodes extend, and form intersections with the second electrode in a plan view, wherein each of the light-emitting elements includes a first element electrode in a bottom surface thereof, and a second element electrode in a top surface thereof, and the method including: arranging a plurality of light-emitting elements at once such that at least respective portions of the light-emitting elements respectively overlap the intersections in a plan view and such that the first electrodes are respectively connected electrically to the first element electrodes.

### Effects of the Invention

According to one aspect of the present invention, a low cost and high resolution display device having light-emitting elements, and a manufacturing method by which it is possible to manufacture this display device at a high efficiency and low cost can be provided.

### BRIEF DESCRIPTION OF THE DRAWINGS

FIG. 1 is a plan view of a display unit of a display device according to Embodiment 1 of the present invention.

FIG. 2 is a cross-sectional view of the display unit of the display device according to Embodiment 1 of the present invention.

FIG. 3 is a cross-sectional view of a state in which the display unit of the display device according to Embodiment 1 of the present invention is bent.

FIG. 4 is a schematic cross-sectional view of an LED element of the display device according to Embodiment 1 of the present invention.

FIG. 5 is a plan view shows a step forming LED elements and a step of mounting the LED elements on a first substrate, which are some steps in the process of manufacturing the display device of Embodiment 1 of the present invention.

FIG. 6 shows cross-sectional views of steps of manufacturing the display device of Embodiment 1 of the present invention.

FIG. 7 is an enlarged view of an LED element in order to describe the path of UV light.

FIG. 8 is a plan view of a display unit of a display device according to a modification example of the present invention.

FIG. 9 is a cross-sectional view of a display unit of a display device according to the modification example of the present invention.

FIG. 10 is a plan view of a display unit of a display device according to another modification example of the present invention.

FIG. 11 is a plan view of first electrodes of a display device according to another modification example of the present invention.

FIG. 12 is a plan view of another example of first electrodes of a display device according to another modification example of the present invention.

FIG. 13 is a cross-sectional view of the display unit of the display device according to Embodiment 2 of the present invention.

FIG. 14 shows cross-sectional views of steps of manufacturing the display device of Embodiment 2 of the present invention.

FIG. 15 is a cross-sectional view of a display unit of a display device according to the modification example of the present invention.

FIG. 16 is a cross-sectional view of the display unit of the display device according to Embodiment 3 of the present invention.

FIG. 17 is a plan view of a first substrate showing an arrangement of a conductive adhesive pattern and LED elements on the first electrodes of a display device according to Embodiment 3 of the present invention.

FIG. 18 shows cross-sectional views of steps of manufacturing the display device of Embodiment 3 of the present invention.

FIG. 19 is a cross-sectional view of the display unit of a display device according to Embodiment 4 of the present invention.

FIG. 20 shows cross-sectional views of steps of manufacturing the display device of Embodiment 4 of the present invention.

FIG. 21 shows cross-sectional views of another example of steps of forming an insulating layer of the display device of Embodiment 4 of the present invention.

FIG. 22 shows cross-sectional views of steps of bonding together substrates of the display device of Embodiment 4 of the present invention.

FIG. 23 is a plan view of the first substrate showing the sizes of the gaps between adjacent first electrodes and the width of electrode surfaces of the LED elements.

FIG. 24 is a plan view of a display surface of a display device according to Embodiment 5 of the present invention.

FIG. 25 is a cross-sectional view of the display surface of the display device according to Embodiment 5 of the present invention.

FIG. 26 is a cross-sectional view of another example of the display surface of the display device according to Embodiment 5 of the present invention.

FIG. 27 is a cross-sectional view of another example of the display surface, including LED elements, of the display device according to Embodiment 5 of the present invention.

FIG. 28 is a cross-sectional view of yet another example of the display surface, including LED elements, of the display device according to Embodiment 5 of the present invention.

FIG. 29 is a drawing for describing a method of manufacturing a display device as a reference example.

FIG. 30 is a drawing for describing a method of manufacturing the display device according to Embodiment 5 of the present invention.

FIG. 31 is a drawing for describing in further detail a method of manufacturing the display device according to Embodiment 5 of the present invention.

FIG. 32 is a cross-sectional view of a display unit obtained by the method of manufacturing the display device according to Embodiment 5 of the present invention.

FIG. 33 is a schematic view for describing a change in concentration of conductive particles in a conduction-contributing region before and after an anisotropic conductive material has been stretched.

FIG. 34 is a cross-sectional view of the display surface of the display device according to Embodiment 6 of the present invention.

FIG. 35 is a drawing for describing a method of manufacturing the display device according to Embodiment 6 of the present invention.

FIG. 36 is a drawing showing the relation between conductive protrusions and an insulating resin layer when the surfaces of the conductive protrusions are fluorine-coated.

FIG. 37 is a drawing showing applicable configurations of the display device of Embodiment 5 and the display device of Embodiment 6.

FIG. 38 is a cross-sectional view of the display surface of the display device according to Embodiment 7 of the present invention.

FIG. 39 is a drawing for describing a method of manufacturing the display device according to Embodiment 7 of the present invention.

FIG. 40 is a drawing for describing steps of dispersing glass spacers.

FIG. 41 is a plan view of an image display device disclosed in Patent Document 1 as a conventional technique.

FIG. 42 is a side view showing the configuration of the image display device disclosed in Patent Document 1 as a conventional technique.

FIG. 43 is a cross-sectional view of a typical LED element that can be used as the light-emitting element of Patent Document 1 as a conventional technique.

### DETAILED DESCRIPTION OF EMBODIMENTS

### Embodiment 1

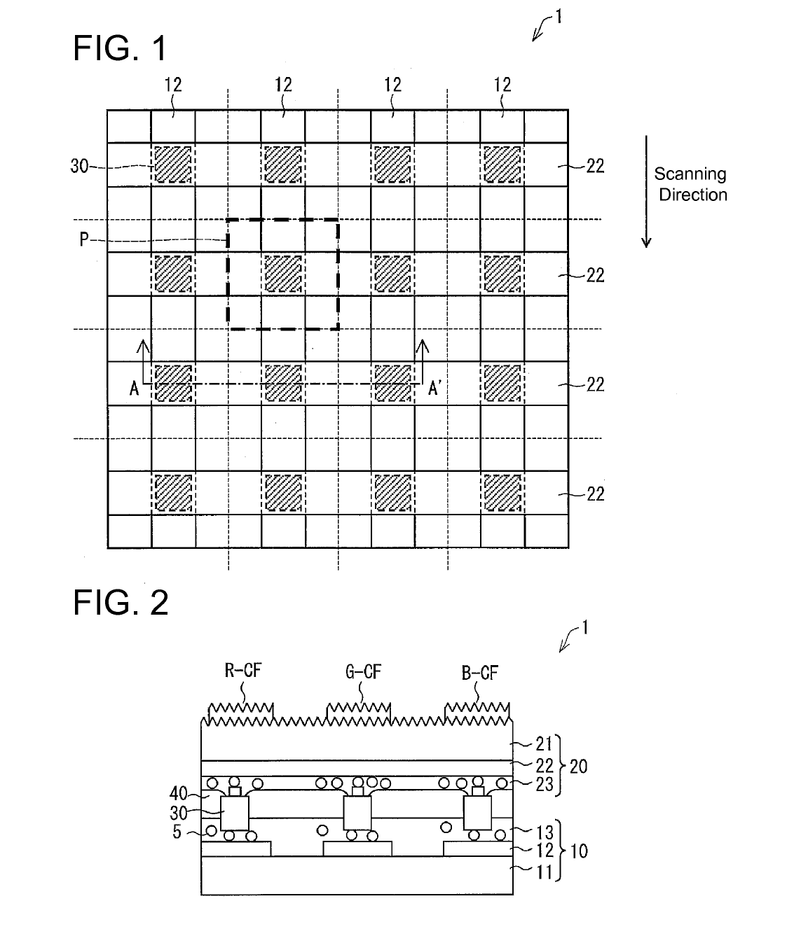

A display device of Embodiment 1 of the present invention will be explained below with reference to FIGS. 1 to 12.

(Display Device)

FIG. 1 is a plan view of a display unit 1 of a display device of the present embodiment. FIG. 2 is a cross-sectional view along the line A-A′ of FIG. 1.

The display device of the present embodiment includes the display unit 1 having a display surface on which images are displayed, and a control unit (not shown) that controls the display of images on the display surface.

As shown in FIG. 2, the display unit 1 of the display device of the present embodiment includes a first substrate 10 and a second substrate 20 disposed to face each other. Also, LED elements 30 and an insulating layer 40 are provided in the area between the first substrate 10 and the second substrate 20.

(First Substrate)

The first substrate 10 includes a film substrate 11 and first electrodes 12 provided on the film substrate 11, and the plurality of first electrodes 12 are arranged in a stripe pattern on the surface of the film substrate 11 facing the second substrate 20. Also a first anisotropic conductive layer 13 (first adhesive layer) is provided on the film substrate 11 so as to cover the first electrodes 12.

The first electrodes 12 are electrically connected to first element electrodes of LED elements 30 to be mentioned later through the first anisotropic conductive layer 13, and together with second electrodes 22 apply a voltage to the LED elements 30.

(Second Substrate)

The second substrate 20 includes a film substrate 21 that is a transparent substrate and second electrodes 22 provided on the film substrate 21, and the plurality of second electrodes 22 are arranged in a stripe pattern on the surface of the film substrate 21 facing the first substrate 10. Also, a second anisotropic conductive layer 23 (second adhesive layer) is provided on the film substrate 21 so as to cover the second electrodes 22.

It is preferable that the first electrodes 12 and the second electrodes 22 be transparent electrodes, and ITO electrodes can be used therefor, for example.

The second electrodes 22 are electrically connected to second element electrodes of LED elements 30 to be mentioned later through a second anisotropic conductive layer 23, and together with the first electrodes 12 apply a voltage to the LED elements 30.

An anisotropic conductive film (ACF) or an anisotropic conductive paste (ACP) can be used as the first and second anisotropic conductive layers 13 and 23.

In an actual display device, pixels P are formed using approximately 6 million LED elements 30, but 16 LED elements 30 are shown in FIG. 1 for description.

The first and second anisotropic conductive layers 13 and 23 are formed by dispersing conductive particles 5 (conductive balls) in a resin, and achieve conduction by the conductive particles 5 being in contact with each other. In other words, as shown in FIG. 2, by providing conductive particles 5 between the first electrodes 12 and the LED elements 30, the first electrodes 12 and the LED elements 30 are electrically connected to each other through the conductive particles 5. Similarly, by providing conductive particles 5 between the second electrodes 22 and the LED elements 30, the second electrodes 22 and the LED elements 30 are electrically connected to each other through the conductive particles 5.

Also, in the film substrate 21, a YAG phosphor (fluorescent layer) may be provided in positions corresponding to where the LED elements 30 are disposed. LED elements 30 that emit blue light or LED elements 30 that emit ultraviolet light can be used. In such a case, light emitted by the LED elements 30 excites the YAG phosphor in the film substrate 21, and visible light is emitted from the film substrate 21, which can contribute to display.

Also, RGB color filters R-CF, G-CF, and B-CF may be provided on the display surface side of the film substrate 21 of the second substrate 20. In this manner, light emitted from the film substrate 21 can be given the respective colors to display images.

As shown in FIG. 2, it is preferable that the surface of the film substrate 21 and the surfaces of the color filters R-CF, G-CF, and B-CF be uneven. In this manner, light from the display unit 1 of the display device of the present embodiment can be efficiently transmitted to display images.

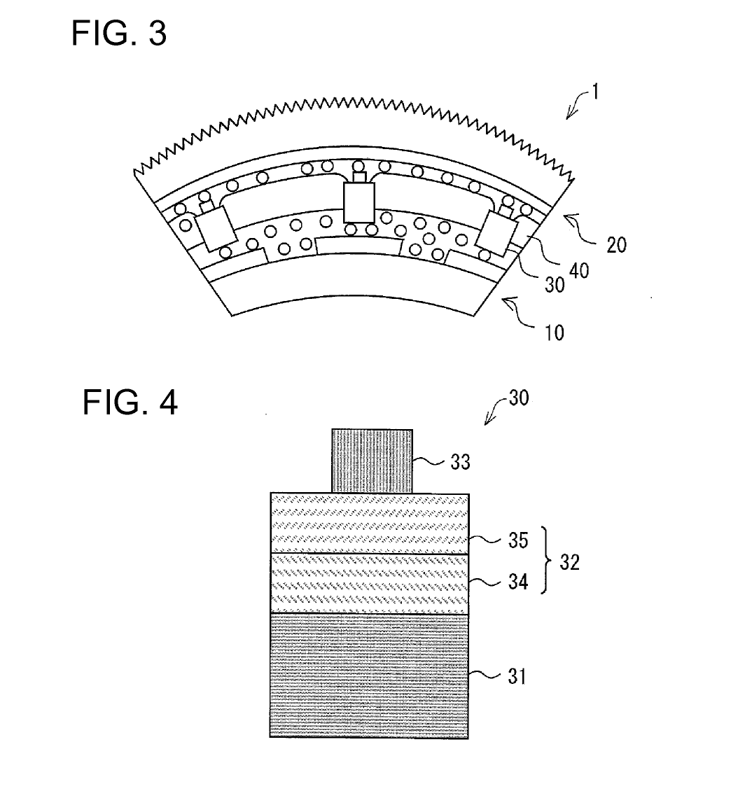

Also, by forming the film substrates 11 and 21 of a deformable material, it is possible to make the display unit 1 deformable, thereby attaining a flexible display as shown in FIG. 3. In order to efficiently transmit light from the LED elements 30, it is preferable that the film substrates 11 and 21 be thin.

In the description below, a case will be described in which the film substrates 11 and 21 are used in the configuration of the display device of the present invention, but a hard substrate such as a glass substrate can be used instead of the film substrates 11 and 21. Also, it is possible to use non-transparent substrates such as metal substrates or ceramic substrates instead of the film substrates 11 and 21.

(Insulating Layer)

An insulating layer 40 is filled into the area between the first substrate 10 and the second substrate 20 where LED elements 30 are not provided.

A transparent resin is used as the insulating layer 40 in the display device of the present embodiment. By providing the insulating layer 40, it is possible to prevent short-circuiting between the first electrodes 12 and the second electrodes 22.

A black resin can also be used as the insulating layer 40. In such a case, it is possible to cut out light that does not contribute to display among the light emitted from the LED elements 30, or in other words, light that does not travel towards the viewer.

(LED Element)

As shown in FIG. 1, the first electrodes 12 and the second electrodes 22 intersect in a plan view. In other words, in a plan view, the first electrode 12 has an intersection that overlaps the second electrode 22.

LED elements 30 (light-emitting elements) are provided in areas between the first substrate 10 and the second substrate 20 in intersecting regions, which are regions where the first electrodes 12 and the second electrodes 22 intersect in a plan view. Here, it is preferable that the gap between adjacent LED elements 30 be three or more times the thickness of the first substrate 10, and even more preferable that the gap be ten times this thickness. Also, it is preferable that the gap between adjacent LED elements 30 be three or more times the combined thickness of the second substrate 20 and the color filters, and even more preferable that the gap be ten times this combined thickness.

In this manner, light emitted from the LED elements 30 is guided inside the display unit 1, and the amount of light that is not emitted outside from the display unit 1 can be reduced. In other words, light emitted by the LED elements 30 can efficiently contribute to display.

The thickness of the first substrate 10 is set to 100 μm, the total thickness of the second substrate 20 and the color filters is set to 100 μm, and the gap between adjacent LED elements 30 is set to 1 mm.

An LED element that emits blue light is used as the LED element 30 in the display device of the present embodiment. However, the configuration is not limited thereto, and color display may be achieved by arranging LED elements that emit red light, LED elements that emit green light, and LED elements that emit blue light. In such a case, color filters and YAG phosphors are unnecessary. In order to keep the cost of the display device low, it is preferable that LED elements that emit one type of light such as blue light be used.

The LED elements 30 are fixed onto the first substrate 10 through the first anisotropic conductive layer 13, and onto the second substrate 20 through the second anisotropic conductive layer 23.

The display unit 1 of the present embodiment is provided with LED elements 30 at the respective intersection regions, and in a plan view, pixels P are formed in positions corresponding to where the LED elements 30 are provided.

Thus, in the display device of the present embodiment, the LED elements 30 can be arranged on the display surface without any loss in area, which allows for a high resolution display device.

(Structure of LED Element)

The structure of the LED element 30 of the present invention will be described with reference to FIG. 4. FIG. 4 is a schematic cross-sectional view of the LED element 30.

The LED element 30 has a structure in which a first element electrode 31, a light-emitting layer 32, and a second element electrode 33 are layered in this order. The first element electrode 31 is provided on the bottom surface of the LED element 30, and the second element electrode 33 is provided on the top surface of the LED element 30. The electrode surface of the first element electrode 31 and the electrode surface of the second element electrode 33 face each other.

The first element electrode 31 is electrically connected to the first electrode 12, the second element electrode 33 is electrically connected to the second electrode 22, and the light-emitting layer 32 is electrically connected to the first element electrode 31 and the second element electrode 33.

The light-emitting layer 32 has a structure in which an N-type semiconductor layer 34 connected to the first element electrode 31 forms a PN junction with a P-type semiconductor layer 35 connected to the second element electrode 33. When a voltage is applied to the LED element 30, electrons and holes in the light-emitting layer 32 move, and holes in the P-type semiconductor layer 35 and the electrons in the N-type semiconductor layer 34 collide and bond together. The energy formed by the bonding of the holes and electrons is outputted as light energy.

By using LED elements 30 having electrodes on the top surface and the bottom surface, it is possible to mount the LED elements 30 with ease by sandwiching the LED elements 30 between the first substrate 10 and the second substrate 20.

The structure of the LED elements 30 of the present embodiment is not limited to that of FIG. 4. The light-emitting layer 32 shown in FIG. 4 may alternatively have a structure in which a P-type semiconductor layer connected to the first element electrode 31 forms a PN junction with an N-type semiconductor layer connected to the second element electrode 33. FIG. 4 is a schematic view of the structure of the LED element 30 and does not accurately show detailed portions.

(Example of Driving Method)

In the display device of the present embodiment, the first electrodes 12 and the second electrodes 22 are sequentially selected, and a voltage is applied between selected electrodes. The display device displays images by applying a voltage to the LED element 30 provided at the intersection between a selected first electrode 12 and second electrode 22 such that the LED element 30 emits light.

In other words, the display device of the present embodiment is of a simple matrix type. A control unit used in a conventional simple matrix display device can be used as the control unit for the display device of the present embodiment.

An example of a method of driving the display device of the present embodiment will be described below.

In FIG. 1, the first electrodes 12 extending in the vertical direction are data electrodes and the second electrodes 22 extending in the horizontal direction are scanning electrodes, and either 0V or 5V is applied to the first electrodes 12.

When a voltage applied to a certain second electrode 22 is 0V (that is, when it is being selected) and the voltage applied to a certain first electrode 12 (data electrode) is 10V, then a voltage of 10V (10V-0V) is applied to the LED element 30 disposed at the intersection between the first electrode and the second electrode 22, causing the LED element 30 to emit light.

On the other hand, when a voltage applied to a certain second electrode 22 is 5V (that is, when it is not being selected) and the voltage applied to a certain first electrode 12 (data electrode) is 10V, then a voltage of 5V (10V-5V) is applied to the LED element 30 disposed at the intersection between the first electrode 12 and the second electrode 22, and the LED element 30 does not emit light.

Also, even if a voltage applied to a certain second electrode 22 is 0V (that is, when it is being selected), if the voltage applied to a certain first electrode 12 (data electrode) is 5V, then a voltage of only 5V (5V-0V) is applied to the LED element 30 disposed at the intersection between the first electrode 12 and the second electrode 22, and the LED element 30 does not emit light.

When a voltage applied to a certain second electrode 22 is 5V (that is, when it is not being selected) and the voltage applied to a certain first electrode 12 (data electrode) is 5V, then no voltage (5V-5V) is applied to the LED element 30 provided at the intersection between the first electrode and the second electrode 22, and the LED element 30 does not emit light.

As the voltage applied to the first electrode 12 (data voltage), 10V or 5V is applied, and a mid-gradation display is performed by pulse width modulation (PWM).

(Method of Manufacturing Display Device)

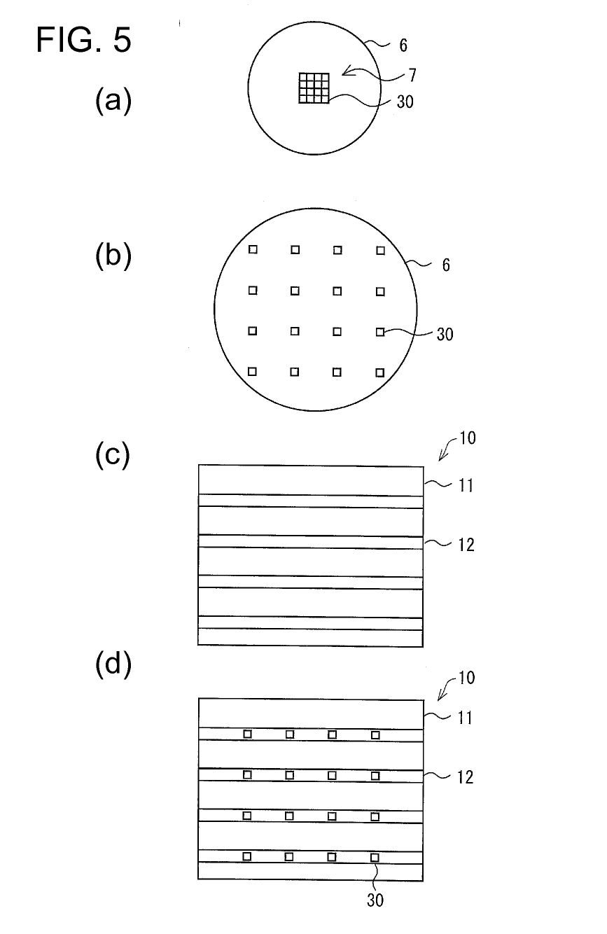

Next a method of manufacturing the display device of the present embodiment will be described with reference to FIGS. 5 to 12. In the description below, depiction of color filters and the like will be omitted.

The method of manufacturing the display device of the present embodiment mainly includes a step of arranging LED elements, a step of forming an insulating layer, and a step of bonding substrates. The three steps above will be described in order below.

(Step of Arranging LED Elements)

First, the step of arranging the LED elements will be described. The step of arranging the LED elements, which is one step in the method of manufacturing the display device of the present embodiment, is a step in which the LED elements 30 are arranged on the first substrate 10. The step of arranging the LED elements includes, as a characteristic step, arranging (mounting) a plurality of LED elements 30 simultaneously on the first substrate 10.

FIG. 5 is a plan view showing the step of forming the LED elements 30 and the step of mounting the LED elements 30 on the first substrate 10.

As shown in FIG. 5(a), an LED wafer 7 is bonded onto a dicing tape 6 (first sheet), and the LED wafer 7 is then diced. As a result, a plurality of LED elements 30 are formed in a matrix on the dicing tape 6. The LED elements 30 formed by dicing are adjacent to each other. The dicing tape 6 stretches by a force applied thereto and is a film having a low restoring force.

Next, as shown in FIG. 5(b), by stretching the dicing tape 6 is stretched up-and-down and left-and-right, which widens the gaps between adjacent LED elements 30. The gaps between adjacent LED elements 30 are adjusted to match the gaps between adjacent first electrodes 12 provided in a stripe pattern on the first substrate 10 and the gaps between adjacent second electrodes 22 provided in a stripe pattern on the second substrate 20.

More specifically, the gaps between the LED elements 30 are adjusted such that when bonding the first substrate 10 to the second substrate 20 to sandwich the LED element 30 therebetween, the LED elements 30 are provided at the intersections between the first electrodes 12 and the second electrodes 22.

At this time, the gaps between the LED elements 30 may be adjusted by providing the LED element 30 between two dicing tapes (first sheet, second sheet) and stretching the dicing tapes.

FIG. 5(c) is a plan view of the first substrate 10, the front surface of which is provided with a first anisotropic conductive layer 13 (not shown). In the first substrate 10 is formed by forming the first electrodes 12 in a stripe pattern on the film substrate 11, and forming the first anisotropic conductive layer 13 (not shown) on the film substrate 11 so as to cover the first electrode 12.

Next, the plurality of LED elements 30 on the dicing tape 6 are transferred to the first substrate 10. At this time, as shown in FIG. 5(d), the LED elements 30 are transferred onto the first substrate 10 such that the LED elements are provided over the first electrodes 12. Alternatively, the LED elements 30 are transferred so as to overlap at least a portion of the first electrodes 12 in a plan view.

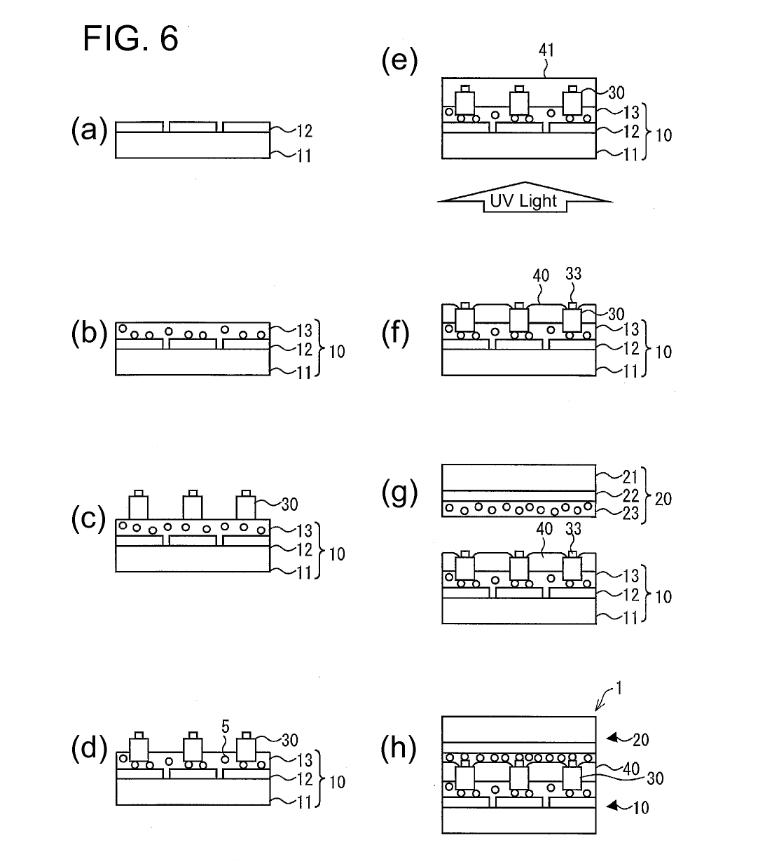

Below, descriptions are made with reference to FIG. 6, which is a cross-sectional view showing the steps of arranging the LED elements. FIG. 6 is a cross-sectional view corresponding to FIG. 2.

FIG. 6(a) is a cross-sectional view showing a state in which the first electrodes 12 are provided on the film substrate 11. As shown in FIG. 6(b), the first anisotropic conductive layer 13 is formed thereon to complete the first substrate 10.

Next, as shown in FIG. 6(c), the plurality of LED elements 30 are simultaneously transferred to the first substrate 10.

Next, as shown in FIG. 6(d), the plurality of LED elements 30 are simultaneously thermocompression bonded to the first substrate 10. As a result, pressure in a direction perpendicular to the substrate surface is applied to the first anisotropic conductive layer 13 between the LED elements 30 and the first electrodes 12, and the first element electrodes (not shown) provided at the bottom surface of the LED elements 30 are electrically connected to the first electrodes 12 through the conductive particles 5 included in the first anisotropic conductive layer 13.

The LED elements 30 are fixed to the first substrate 10 by the adhesive force of the first anisotropic conductive layer 13.

During the above-mentioned thermocompression bonding, pressure in a direction parallel to the substrate surface is not applied to the first anisotropic conductive layer 13, which means that conduction between conductive particles 5 does not occur in a planar manner, which means that neither short-circuiting between adjacent LED elements 30 nor short-circuiting between adjacent first electrodes 12 due to the conductive particles 5 occurs.

As described above, the LED elements 30 used in the display device of the present embodiment have first element electrodes 31 provided at the bottom surface and second element electrodes 33 provided at the top surface.

The LED element 30 has electrodes on both the top surface and bottom surface, and thus, it is possible to electrically connect the electrode on the LED element 30 to the electrodes provided on the substrates by providing the LED element 30 between the first electrode 12 provided on the first substrate 10 and the second electrode 22 provided on the second substrate 20 even if the arrangement of the LED element 30 is slightly offset.

Thus, according to the method of manufacturing the display device of the present embodiment, a high degree of positioning accuracy is not required when arranging the LED elements 30, and it is possible to manufacture the display device including LED elements 30 with ease and at a low cost.

(Step of Forming Insulating Layer)

Next, the step of forming the insulating layer will be described. The step of forming the insulating layer, which is one step in the method of manufacturing the display device of the present embodiment, is a step in which the insulating layer 40 to be provided between the first substrate 10 and the second substrate 20 is formed on the first substrate 10.

A resin can be formed as the insulating layer 40, for example. In such a case, the resin may be a UV curable (photocurable) resin or a thermosetting resin.

In the description below, the step of forming the insulating layer 40 of a UV curable resin 41 will be described.

First as shown in FIG. 6(e), the UV curable resin 41, which has not been cured yet (in a state prior to being cured), is disposed over the first substrate 10 on which the LED elements 30 have been arranged in the step of arranging the LED elements such that the UV curable resin 41 covers the LED elements 30.

Next, as shown in FIG. 6(e), UV light is radiated from the rear of the first substrate 10 to cure the UV curable resin 41. Here, the rear of the first substrate 10 refers to the surface of the first substrate 10 not provided with the LED elements 30.

The LED elements 30 are non-transparent and do not allow through light. Thus, by radiating light from the rear of the first substrate 10, light does not reach beyond the second element electrodes 33 of the LED elements 30, which means that the UV curable resin 41 is not cured above the second element electrode 33.

The film substrate 11 and the first electrodes 12 may be transparent or non-transparent.

Next, as shown in FIG. 6(f), the uncured portion of the UV curable resin 41 is removed by etching, which leaves remaining only the cured UV curable resin 41 (post-cured), thereby forming the insulating layer 40. As described above, the portion of the UV curable resin 41 above the second element electrode 33 remains uncured, and thus, the formed insulating layer 40 does not cover the second element electrode 33 at the top surface of the LED element 30. In other words, the second element electrode 33 is exposed.

The area above the first substrate 10 and between adjacent LED elements 30 is covered by the insulating layer 40.

By not covering the second element electrode 33 with the insulating layer 40, it is possible to electrically connect the second electrode 22 provided on the second substrate 20 to the second element electrode 33 by disposing the second substrate 20 over the LED element 30 in the step of bonding the substrates to be mentioned later.

By covering the area over the first substrate 10 and between adjacent LED elements 30 with the insulating layer 40, the first electrode 12 and the second electrode 22 are not electrically connected through the first and second anisotropic conductive layers 13 and 23 even when the first substrate 10 and the second substrate 20 are bonded together in the step of bonding the substrates to be mentioned later. In other words, there is no short-circuiting.

It is preferable that the insulating layer 40 not cover the second element electrode 33 but cover the entire side face of the LED element 30, and furthermore reach the upper surface thereof.

As described with reference to FIG. 4, the LED element 30 has a structure in which a PN junction is formed in the light-emitting layer 32. If the conductive particles 5 of the first or second anisotropic conductive layer 13 or 23 come into contact with both the P-type semiconductor layer 35 and the N-type semiconductor layer 34 at a side face of the LED element 30, this would result in a short-circuit between the P-type semiconductor layer 35 and the N-type semiconductor layer 34 through the conductive particles 5, which would prevent the LED element 30 from emitting light normally.

Thus, it is preferable that the side face of the LED element 30 be protected by the insulating layer 40. In the method of manufacturing the display device of the present embodiment, the insulating layer 40 can be formed to cover the side face of the LED element 30 and furthermore reach the upper surface of the LED element 30.

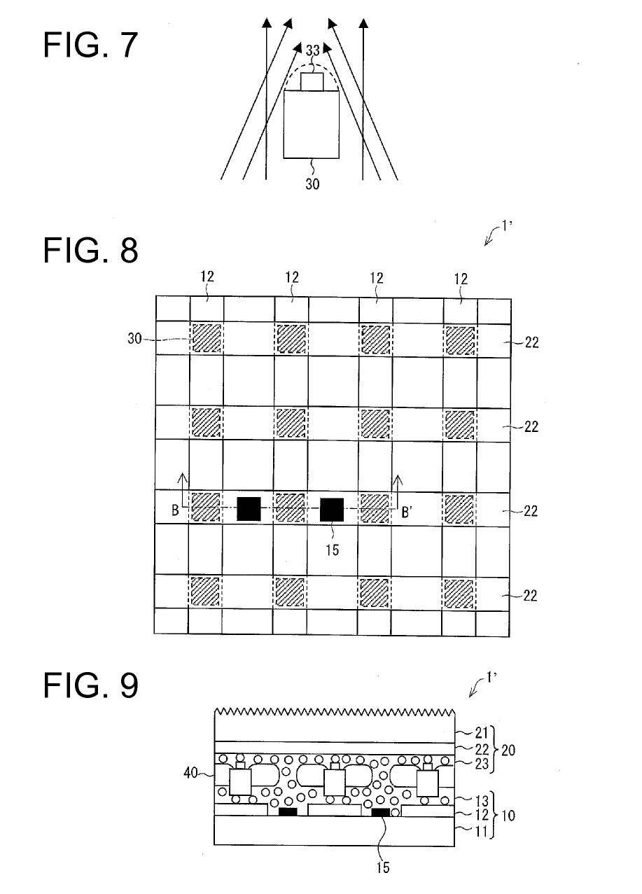

Below, a detailed description will be made with reference to FIG. 7.

FIG. 7 is an enlarged view of an LED element 30 in order to describe the path of UV light. As shown in FIG. 7, the second element electrode 33 protrudes from the top surface of the LED element 30. UV light does all not travel in the same direction like a laser beam but in various directions.

Thus, a portion of the UV light radiated from the rear of the first substrate 10 travels towards the upper surface of the LED element 30. However, a shadow is formed in the region depicted with a broken line in the image (vicinity of the center of the upper surface of the LED element 30) and UV light does not reach here.

Thus, UV light reaches the edge of the upper surface of the LED element 30 and the UV curable resin 41 is cured here. UV light does not reach the area over the second element electrode 33 and the UV curable resin 41 is not cured here.

Thus, the cured UV curable resin 41 (insulating layer 40) is formed on the edge of the upper surface of the LED element 30. In particular, the cured UV curable resin 41 (insulating layer 40) is formed around the second element electrode 33 on the upper surface of the LED element 30.

(Step of Bonding Substrates)

Next, the step of bonding the substrates will be described. The step of bonding the substrates, which is a step in the method of manufacturing the display device of the present embodiment, is a step following the step of forming the insulating layer in which the LED elements 30, the insulating layer 40, and the second substrate 20 are bonded.

In the present step, as shown in FIG. 6(g), the second substrate 20 is bonded to the LED elements 30 and the insulating layer 40. At this time, the substrates are bonded to each other such that the second element electrodes 33 and the second electrodes 22 face each other. As a result, the second electrodes 22 of the second substrate 20 and the second element electrodes 33 of the LED elements 30 are electrically connected to each other.

The second anisotropic conductive layer 23 may first be formed to cover the LED elements 30 and the insulating layer 40, with the second electrodes 22 and the film substrate 21 being separately bonded.

As shown in FIG. 6(h), after bonding the LED elements 30 and the insulating layer 40 to the second substrate 20, the second substrate 20 is thermocompression bonded.

As a result, pressure in a direction perpendicular to the substrate surface is applied to the second anisotropic conductive layer 23 between the LED elements 30 and the second electrodes 22, and the second element electrodes 33 provided at the bottom surface of the LED elements 30 are electrically connected to the second electrodes 22 through the conductive particles 5 included in the second anisotropic conductive layer 23.

The second substrate 20, and the LED elements 30 and first substrate 10 can be bonded and fixed to each other by the adhesive force of the second anisotropic conductive layer 23.

In this manner, it is possible to manufacture the display unit 1 of the display device of the present embodiment.

(Modification Example 1)

Another preferable aspect of the display device of the present embodiment will be described as a modification example with reference to FIG. 8.

FIG. 8 is a plan view of a display unit 1′ of a display device of the present modification example, and FIG. 9 is a cross-sectional view along the line B-B′ of FIG. 8.

As shown in FIG. 9, in the present modification example, the first anisotropic conductive layer 13 and the second anisotropic conductive layer 23 are in contact with each other. As a result, a stronger bond can be formed between the first substrate 10 and the second substrate 20.

However, if the first anisotropic conductive layer 13 and the second anisotropic conductive layer 23 are in contact with each other in the vicinity of the intersections, this would result in a short-circuit between the first electrode 12 and the second electrode 22, and thus, as shown in FIG. 9, the first anisotropic conductive layer 13 and the second anisotropic conductive layer 23 are bonded to each other in areas other than the intersections.

A method suited to manufacturing the display device of the present modification example will be described.

First, a light-shielding member 15 is formed on the film substrate 11 in areas other than the intersections. The light-shielding member 15 simply needs to block light, and thus, a metal piece such as aluminum may be used, for example.

As a result, when UV light is radiated from the rear of the first substrate 10 during the step of forming the insulating layer, the light-shielding member 15 blocks the UV light. As a result, no light is radiated on portions of the UV curable resin 41 corresponding in position to the light-shielding member 15 in a plan view, and thus, these portions are not cured.

Next, the uncured UV curable resin 41 is removed, leaving remaining only the cured portion of the UV curable resin 41. As a result, an insulating layer 40 having penetrating holes over the light-shielding members 15 is formed.

Then, in the step of bonding the substrates, the second substrate 20 is bonded to the first substrate 10, and through thermocompression bonding, the second anisotropic conductive layer 23 penetrates the penetrating hole, causing the first anisotropic conductive layer 13 to be bonded to the second anisotropic conductive layer 23.

In this manner, it is possible to manufacture the display device of the modification example. In FIG. 8, an example is shown in which only two light-shielding members 15 are provided, but light-shielding members 15 may additionally be provided in other positions.

(Modification Example 2)

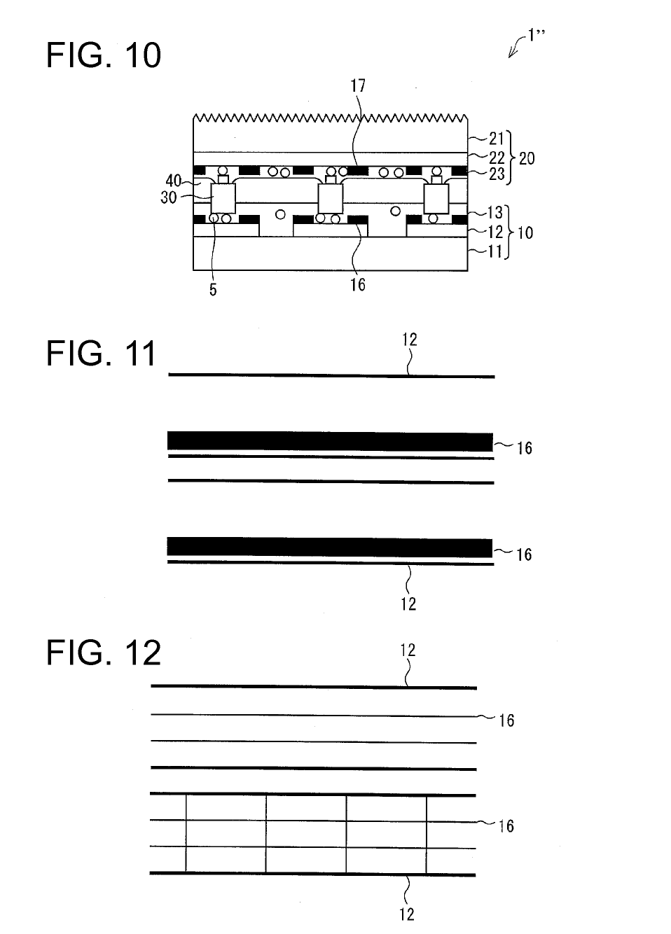

Another preferable aspect of the display device of the present embodiment will be described as a modification example with reference to FIGS. 10 to 12. FIG. 10 is a cross-sectional view of a display unit 1″ of a display device of the present modification example, and FIGS. 11 and 12 are plan views of first electrodes of the display unit 1″.

In the display device of the present embodiment, it is preferable that the first electrodes 12 and the second electrodes 22 be transparent electrodes.

In particular, it is preferable that the second electrode 22, which is the electrode towards the display surface side in relation to the LED element 30, be a transparent electrode in order to efficiently allow light from the LED element 30 to contribute to display.

Also, it is preferable that the first electrode 12, which is the electrode towards the rear of the LED element 30, be a transparent electrode in order for the display device to be a transparent display.

However, if the first electrodes 12 or the second electrodes 22 are made of transparent electrodes such as ITO, there are cases in which the resistance of the transparent electrodes is not sufficiently low, which causes the waveform of the image control signal to break down, resulting in the intended image not being displayed and display unevenness.

Thus, as shown in FIGS. 10 to 12, the display device of the present modification example has metal electrodes 16 (metal wiring lines) formed parallel to (overlapping) the first electrodes 12. Aluminum, molybdenum, tungsten, copper, and the like can be used for the metal electrode 16, for example.

As shown in the upper portion of FIG. 12, a plurality of metal electrodes 16 may be provided on each first electrode 12. Alternatively, as shown in the lower portion of FIG. 12, the metal electrodes 16 may be provided in a mesh on the first electrode 12.

If the metal electrodes 16 are formed in parallel with the first electrodes 12, then there is a risk of decreased display quality due to the metal electrodes 16 reflecting external light entering the display unit 1″ of the display device, and thus, as shown in FIG. 10, it is preferable that light-shielding layers 17 be provided on the display surface side of the metal electrodes 16. The light-shielding layer 17 may be provided on the second substrate 20, for example. Here, the light-shielding layer 17 is provided to decrease reflectance, and a black resin, Cr, or the like can be used for the light-shielding layer 17.

If the metal electrodes 16 are formed in parallel with the first electrodes 12, then in the step of forming the insulating layer, there is a risk that the metal electrodes 16 block the UV light to the UV curable resin 41.

Thus, it is preferable that the metal electrodes 16 be as thin as possible. When the metal electrodes 16 are sufficiently thin, this allows UV light to reach the area above the metal electrodes 16, which means that UV light also reaches areas of the UV curable resin 41 above the metal electrodes 16.

Also, if the metal electrodes 16 are sufficiently thin, then even if UV light does not reach portions of the UV curable resin 41 above the metal electrodes 16, the curing of the UV curable resin 41 spreads and portions over the metal electrode 16 are also cured.

By the measures above, even if the metal electrodes 16 are formed in parallel with the first electrodes 12, it is possible to cure the UV curable resin 41 normally by radiating UV light from the rear of the first substrate 10.

Additionally, the following method can be used in order to reliably cure portions of the UV curable resin 41 over the metal electrodes 16.

That is, during the step of forming the insulating layer, UV light is first radiated from the rear of the first substrate 10 to cure the UV curable resin 41. Next, a mask having openings in portions where the metal electrodes 16 are provided is formed to cover the UV curable resin 41 and the LED elements 30, and UV light is radiated from the front (display surface side) of the first substrate 10. This allows portions of the UV curable resin 41 over the metal electrodes 16 to be reliably cured.

### Embodiment 2

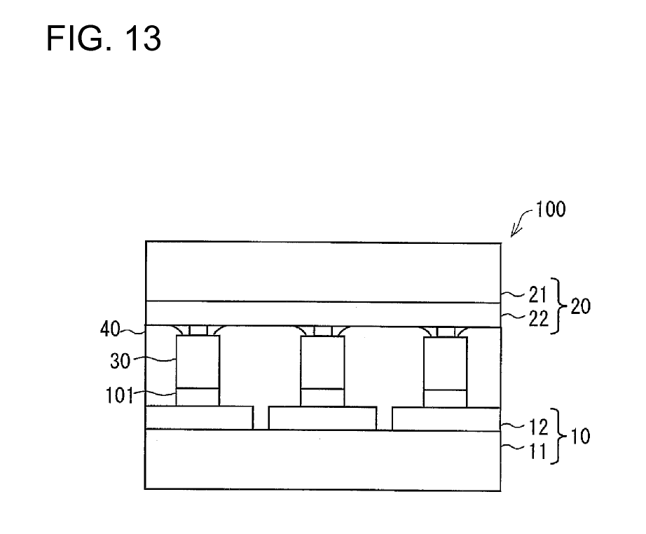

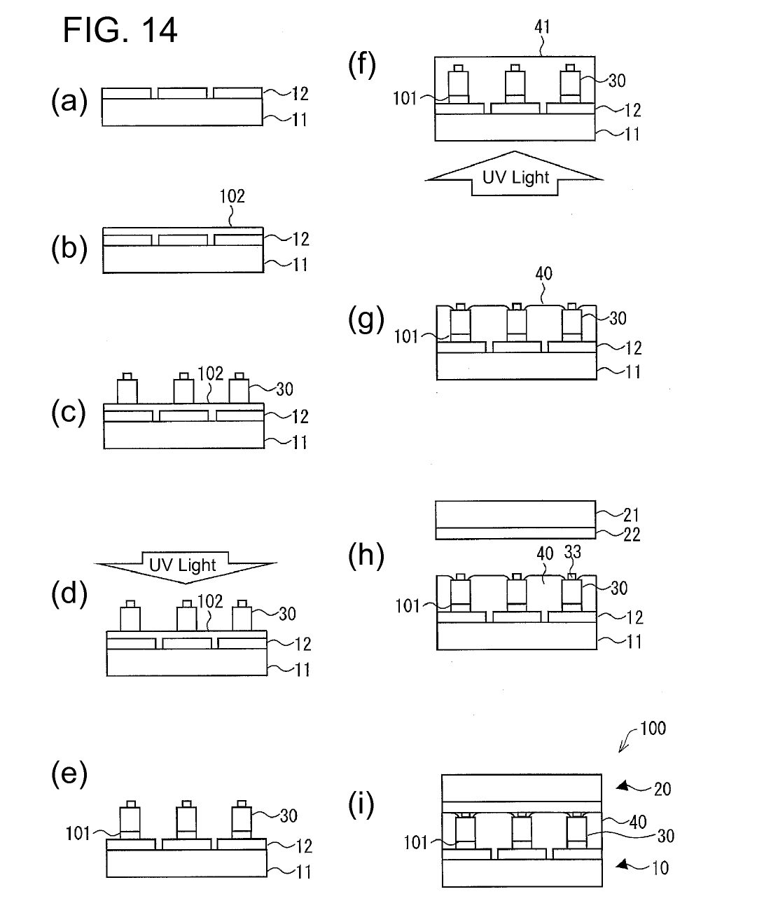

Another embodiment according to the present invention is as described below with reference to FIGS. 13 to 15. For ease of explanation, the members having the same functions as described in the previous embodiment are given the same reference characters, and the descriptions thereof are omitted.

FIG. 13 is a cross-sectional view of a display unit 100 of a display device of the present embodiment.

As shown in FIG. 13, unlike the display unit 1 of Embodiment 1, the display unit 100 of the display device of the present embodiment does not have first and second anisotropic conductive layers 13 and 23.

The first substrate 10 has conductive resins 101 (first adhesive layer) provided on the first electrodes 12, and the first substrate 10 and the LED elements 30 are bonded to each other through the conductive resins 101. Also, the first electrode 12 and the first element electrode 31 are electrically connected through the conductive resin 101.

Additionally, the second electrode 22 and the second element electrode 33 are electrically connected by being in direct contact with each other.

The display device of Embodiment 1 has first and second anisotropic conductive layers 13 and 23, and the first and second anisotropic conductive layers 13 and 23 are also provided in areas between the LED elements 30. The conductive particles 5 included in the first and second anisotropic conductive layers 13 and 23 sometimes scatter light.

By contrast, the display device of the present embodiment uses conductive resins 101 instead of the first and second anisotropic conductive layers 13 and 23. Also, the areas between the LED elements 30 are filled with the insulating layer 40. By using a transparent material for the insulating layer 40, it is possible to mitigate a decrease in display quality resulting from light emitted from the LED elements 30 being scattered.

Also, by providing conductive members only in necessary locations and not in unnecessary locations, the possibility of a short-circuit can be decreased.

(Method of Manufacturing Display Device)

Next a method of manufacturing the display device of the present embodiment will be described with reference to FIG. 14. The step of arranging the LED elements, the step of forming the insulating layer, and the step of bonding the substrates will be described in that order below. FIG. 14 corresponds to FIG. 2 and is a cross-sectional view of a portion of the display unit 100.

(Step of Arranging LED Elements)

First, the step of arranging the LED elements 30 will be described. Similar to the method of manufacturing the display device of Embodiment 1, the method of manufacturing the display device of the present embodiment also includes in the step of arranging the LED elements, as a characteristic step, arranging (mounting) the plurality of LED elements 30 simultaneously on the first substrate 10.

Below, the step of arranging the LED elements will be described together with the step of forming the first substrate 10 of the display device of the present embodiment.

The same method of adjusting the gap between the plurality of LED elements 30 using the dicing tape can be used as described with reference to FIG. 5, and thus, descriptions thereof are omitted.

First, as shown in FIG. 14(a), the first electrodes 12 are formed in a stripe pattern on the film substrate 11, and as shown in FIG. 14(b), a positive conductive resin 102 is formed as the conductive resin 101 over the film substrate 11 to cover the first electrodes 12.

A positive resist having conductive particles mixed therein can be used as the positive conductive resin 102.

Next, the plurality of LED elements 30 are simultaneously transferred onto the positive conductive resin 102. At this time, as shown in FIG. 14(c), the LED elements 30 are transferred onto the first substrate 10 such that the LED elements are provided over the first electrodes 12. Alternatively, the LED elements 30 are transferred so as to overlap at least a portion of the first electrodes 12 in a plan view.

Next, as shown in FIG. 14(d), UV light is radiated from the rear of the first substrate 10 to etch the positive conductive resin 102. As a result, as shown in FIG. 14(e), exposed portions of the positive conductive resin 102 are removed, while portions thereof shielded from light by having the LED elements 30 stacked thereon are left remaining.

Portions of the positive conductive resin 102 that are left remaining are the conductive resins 101 of the display device of the present embodiment.

In the step of arranging the LED elements above, an anisotropic conductive paste can be used instead of the positive conductive resin 102 for the conductive resins 101. A so-called anisotropic conductive paste (ACP) can be used as the anisotropic conductive paste.

Prior to transferring the LED elements 30, an anisotropic conductive paste is coated in advance on the first electrodes 12 in positions corresponding to where the LED elements 30 are to be transferred. The anisotropic conductive paste may alternatively be screen printed on the first electrodes 12. In this manner, as shown in FIG. 14(e), it is possible to obtain the first substrate 10 on which the LED elements 30 are disposed.

(Step of Forming Insulating Layer)

As shown in FIGS. 14(f) to 14(g), it is possible to use the step of forming the insulating layer described in the method of manufacturing the display device of Embodiment 1 for the step of forming the insulating layer in the method of manufacturing the display device of the present embodiment, and thus, descriptions thereof are omitted.

(Step of Bonding Substrates)

Next, the step of bonding the substrates will be described.

The second substrate 20 of the display device of the present embodiment does not include a second anisotropic conductive layer 23.

Thus, as shown in FIG. 14(h), the LED elements 30 and the insulating layer 40 are bonded to the second substrate 20 such that the second element electrodes 33 of the LED elements 30 are directly in contact with the second electrodes 22 of the second substrate 20.

By vacuum-sealing the LED elements 30, the insulating layer 40, and the second substrate 20, the LED elements 30 and insulating layer 40 can be adhered to the second substrate 20, thereby bonding them together.

In this manner, it is possible to manufacture the display device of the present embodiment.

As long as the insulating layer 40 has adhesive properties, it is possible to bond the second substrate 20 thereto by thermocompression bonding or thermosetting the second substrate 20 to the insulating layer 40.

In this manner, it is possible to manufacture the display device of the present embodiment.

It is also possible to use the step of bonding the substrates described in the method of manufacturing the display device of Embodiment 1 for the step of bonding the substrates in the method of manufacturing the display device of the present embodiment.

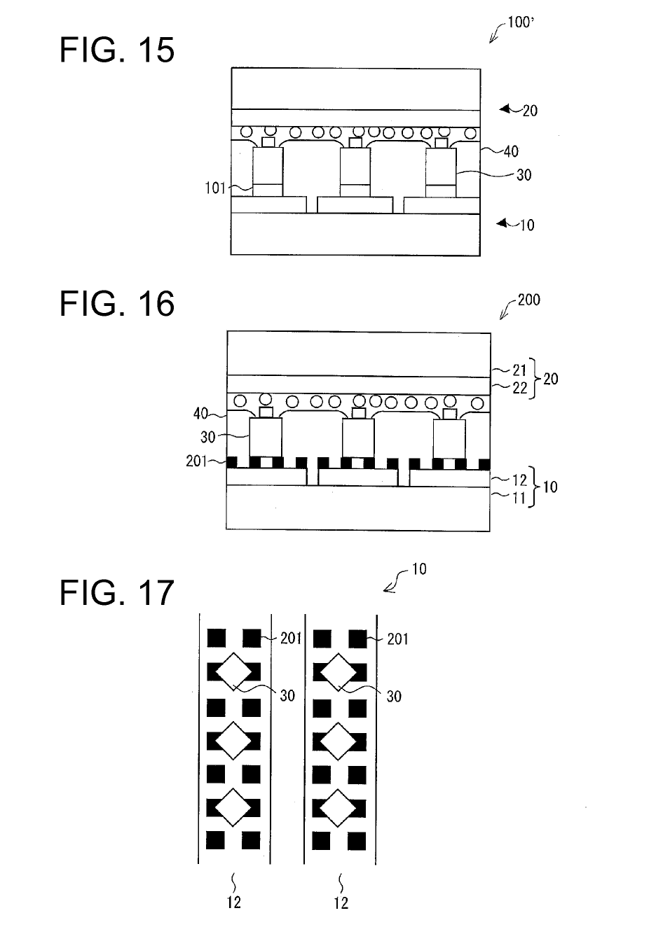

A display unit 100′ of a display device manufactured using the step of bonding the substrates in the method of manufacturing the display device of Embodiment 1 is shown in FIG. 15 as a modification example of Embodiment 2.

### Embodiment 3

Another embodiment according to the present invention is as described below with reference to FIGS. 16 to 18. For ease of explanation, the members having the same functions as described in the previous embodiments are given the same reference characters, and the descriptions thereof are omitted.

FIG. 16 is a cross-sectional view of a display unit 200 of a display device of the present embodiment.

As shown in FIG. 16, unlike the display unit 1 of Embodiment 1, the display unit 200 of the display device of the present embodiment does not have a first anisotropic conductive layers 13.

The first substrate 10 has a conductive adhesive 201 (first adhesive layer) provided on the first electrode 12. The conductive adhesive 201 is not disposed to cover the entire upper surface of the first electrode 12, and the first electrode 12 has exposed portions not covered by the conductive adhesive 201.

The first substrate 10 and the LED element 30 are bonded to each other by the conductive adhesive 201. Also, the first electrode 12 and a first element electrode 31 are electrically connected through the conductive adhesive 201.

The conductive adhesive 201 can be made by mixing carbon powder into a resin paste, for example. The conductive adhesive 201 has a low transmittance of light and a high conductivity compared to the first and second anisotropic conductive layers 13 and 23. Also, whereas the first and second anisotropic conductive layers 13 and 23 exhibit conductive properties by pressure being applied thereon and conductive particles 5 coming into contact, the entire conductive adhesive 201 is conductive without any pressure being applied thereon.

Thus, the conductive adhesive 201 is not formed across adjacent first electrodes 12 in order to prevent short-circuiting between the adjacent first electrodes 12.

Also, as described above, the transmittance of light by the conductive adhesive 201 is low, but by providing the conductive adhesive 201 such that the first electrode 12 has exposed portions as in the display device of the present embodiment, light transmittance in the first substrate 10 is improved, allowing for a transparent display.

In order to bond the LED elements 30 to the first substrate 10, it is preferable that the LED elements 30 be provided on the conductive adhesive 201.

Thus, it is preferable that the gaps in the arrangement pattern (coating pattern) of the conductive adhesive 201 be less than the width of the bottom surface of the LED element 30.

FIG. 17 is a plan view of the first substrate showing an arrangement of the conductive adhesive pattern and the LED elements on the first electrodes.

Typically, the LED elements 30 are obtained by dicing one LED wafer, and thus, as shown in FIG. 17, the LED elements 30 have a rectangular shape (and in particular, a square shape) in a plan view.

As shown in FIG. 17, the conductive adhesive 201 is provided in two rows at equally spaced intervals in the extension direction of the first electrodes 12.

On the other hand, each of the LED elements 30 is square in a plan view, and is provided on the conductive adhesive 201 such that one of the diagonal lines thereof is perpendicular to the extension direction of the first electrode 12.

In this manner, it is possible to efficiently put the first element electrode 31 of the LED element 30 in contact with the conductive adhesive 201 arranged in a two row pattern, thereby electrically connecting the first electrode 12 to the second element electrode 33.

Thus, it is possible to further reduce the area taken up by the conductive adhesive 201 on the first electrode 12, and it is possible to attain a transparent display with a higher light transmittance.

The pattern of the conductive adhesive and the arrangement of the LED elements shown in FIGS. 16 and 17 are merely one example, and the display device of the present embodiment is not limited to this configuration.

(Method of Manufacturing Display Device)

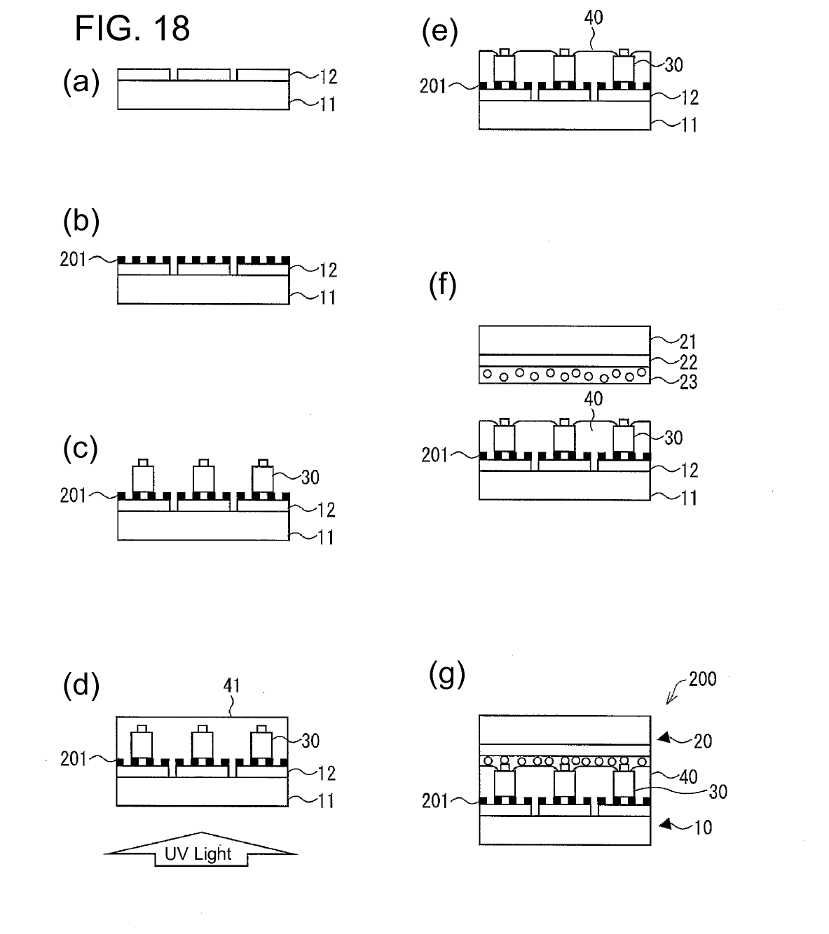

Next a method of manufacturing the display device of the present embodiment will be described with reference to FIG. 18. The step of arranging the LED elements, the step of forming the insulating layer, and the step of bonding the substrates will be described in that order. FIG. 18 corresponds to FIG. 2 and is a cross-sectional view of a portion of the display unit 200.

(Step of Arranging LED Elements)

First, the step of arranging the LED elements 30 will be described. Similar to the method of manufacturing the display device of Embodiment 1, the method of manufacturing the display device of the present embodiment also includes in the step of arranging the LED elements, as a characteristic step, arranging (mounting) the plurality of LED elements 30 simultaneously on the first substrate 10.

Below, the step of arranging the LED elements will be described together with the step of forming the first substrate 10 of the display device of the present embodiment.

The same method of adjusting the gap between the plurality of LED elements 30 using the dicing tape and transferring the LED elements 30 onto the first substrate 10 can be used as described with reference to FIG. 5, and thus, descriptions thereof are omitted.

First, as shown in FIG. 18(a), the first electrodes 12 are formed in a stripe pattern on the film substrate 11, and as shown in FIG. 18(b), a conductive adhesive 201 is formed over the first electrodes 12 to cover a portion of the first electrodes 12.

The conductive adhesive 201 can be formed by coating using a nozzle, screen printing, or the like, for example.

Next, the plurality of LED elements on the dicing tape are transferred to the first substrate 10.

Next, the conductive adhesive 201 is cured by a method suited to the conductive adhesive 201. If the binder of the conductive adhesive 201 is an epoxy resin, for example, then it can be cured by heat.

In this manner, it is possible to obtain the first substrate 10 on which the LED elements 30 are disposed.

(Step of Forming Insulating Layer)

It is possible to use the step of forming the insulating layer described in the method of manufacturing the display device of Embodiment 1 for the step of forming the insulating layer in the method of manufacturing the display device of the present embodiment, and thus, a portion of the descriptions thereof are omitted.

The step of forming the insulating layer, which is one step in the method of manufacturing the display device of the present embodiment, is a step in which the insulating layer 40 to be provided between the first substrate 10 and the second substrate 20 is formed on the first substrate 10.

First, as shown in FIG. 18(d), the UV curable resin 41, which has not been cured yet, is disposed over the first substrate 10 on which the LED elements 30 have been arranged in the step of arranging the LED elements such that the UV curable resin 41 covers the LED elements 30.

Next, UV light is radiated from the rear of the first substrate 10 to cure the UV curable resin 41.

At this time, the first electrode 12 has exposed portions on the top surface thereof where the conductive adhesive 201 is not provided. Thus, UV light passes through the exposed portions and is radiated onto the UV curable resin 41 provided on the first substrate 10.

In this manner, as shown in FIG. 18(d), the insulating layer 40 can be formed in the same manner as the step of forming the insulating layer in the method of manufacturing the display device of Embodiment 1.

(Step of Bonding Substrates)

As shown in FIGS. 18(f) to 18(g), it is possible to use the step of forming the insulating layer described in the method of manufacturing the display device of Embodiment 1 or the step of forming the insulating layer described in the method of manufacturing the display device of Embodiment 2 for the step of forming the insulating layer in the method of manufacturing the display device of the present embodiment, and thus, descriptions thereof are omitted.

### Embodiment 4

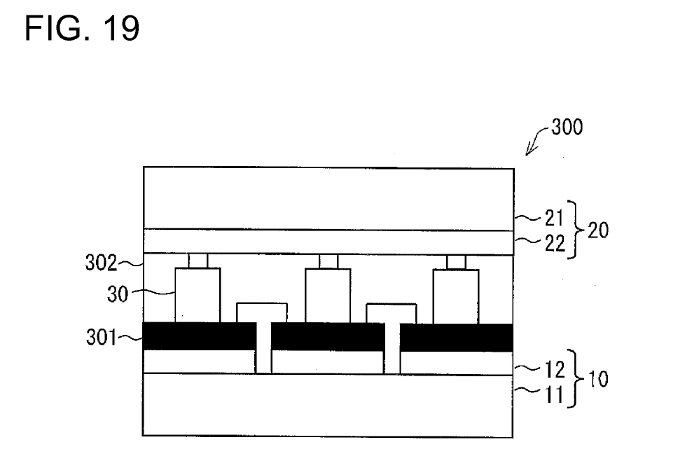

Another embodiment according to the present invention is as described below with reference to FIGS. 19 to 22. For ease of explanation, the members having the same functions as described in the previous embodiments are given the same reference characters, and the descriptions thereof are omitted.

FIG. 19 is a cross-sectional view of a display unit 300 of a display device of the present embodiment.

As shown in FIG. 19, the configuration of the display unit 300 of the display device of the present embodiment is similar to that of the display unit 200 of Embodiment 3. However, unlike the display unit 200, the display unit 300 is provided with a conductive adhesive 301 (first adhesive layer) covering the top surface of the first electrode 12.

In the display device of the present embodiment, it is possible to more reliably ensure conduction between the first electrode 12 and the first element electrode 31 compared to the display device of Embodiment 3.

Also, in the display device of the present embodiment, an adhesive 302 for bonding the first substrate 10 to the second substrate 20 is provided in an area between the first substrate 10 and the second substrate 20 but where the LED elements 30 are not disposed.

In this manner, bonding strength between the first substrate 10 and the second substrate 20 is ensured.

(Method of Manufacturing Display Device)

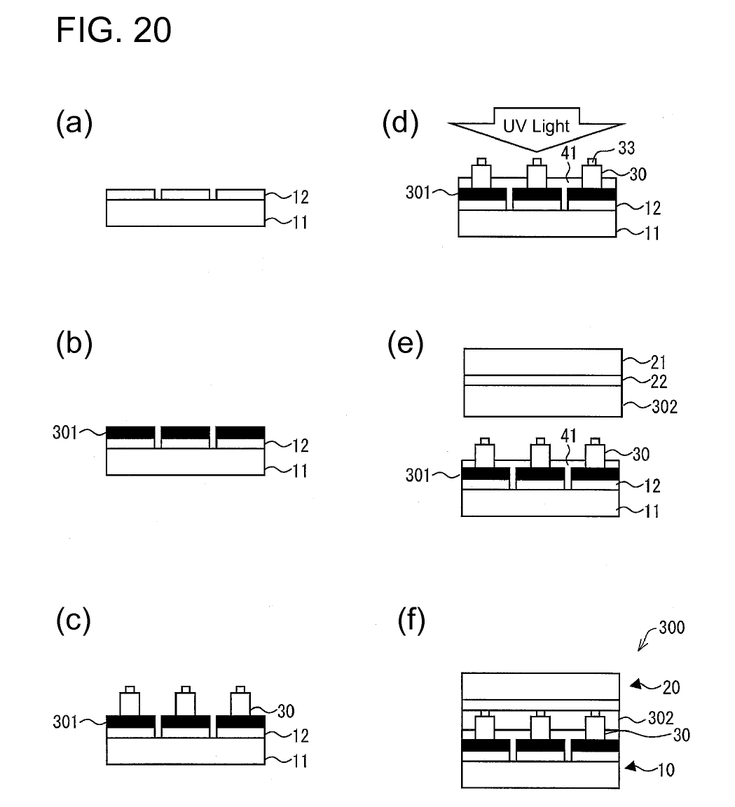

Next a method of manufacturing the display device of the present embodiment will be described with reference to FIG. 20. The step of arranging the LED elements, the step of forming the insulating layer, and the step of bonding the substrates will be described in that order. FIG. 20 corresponds to FIG. 2 and is a cross-sectional view of a portion of the display unit 300.

(Step of Arranging LED Elements)

First, the step of arranging the LED elements 30 will be described. Similar to the method of manufacturing the display device of Embodiment 1, the method of manufacturing the display device of the present embodiment also includes in the step of arranging the LED elements, as a characteristic step, arranging (mounting) the plurality of LED elements 30 simultaneously on the first substrate 10.

As shown in FIGS. 20(a) to 20(c), it is possible to attain a first substrate 10 provided with LED elements 30 by a step similar to the step of arranging the LED elements in the display device of Embodiment 3.

However, the step of arranging the LED elements of the present embodiment differs from step of arranging the LED elements in the display device of Embodiment 3 in that the conductive adhesive 301 is formed on the entire top surface of the first electrode 12.

(Step of Forming Insulating Layer)

There are two steps that can be used as the step of forming the insulating layer in the display device of the present embodiment, and each of these steps will be described.

(First Method)

In the first method, as shown in FIG. 20(d), the UV curable resin 41 is first coated onto the first substrate 10 on which the LED elements 30 have been disposed such that the second element electrodes 33 of the LED elements 30 are not covered.

The UV curable resin 41 is coated by placing the tip of the nozzle for coating the UV curable resin 41 at a position below the second element electrode 33, for example. In this manner, it is possible to coat the UV curable resin 41 onto the first substrate 10 without covering the second element electrodes 33.

Next, UV light is radiated from the front of the first substrate 10 to cure the UV curable resin 41, thereby forming the insulating layer 40.

With the steps above, the second element electrodes 33 are exposed, and the insulating layer 40 covering the area over the first substrate 10 and between the LED elements 30 can be formed.

In this manner, it is possible to prevent short-circuiting between adjacent LED elements 30 and short-circuiting between adjacent first electrodes 12.

(Second Method)

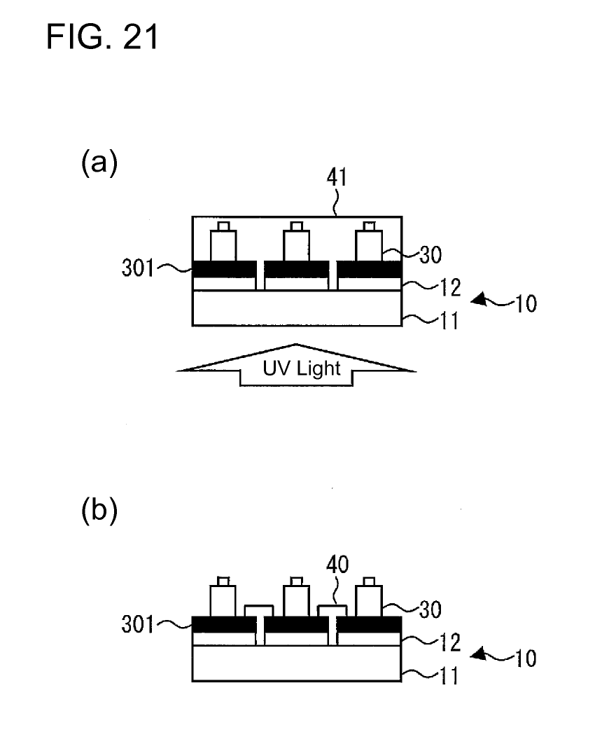

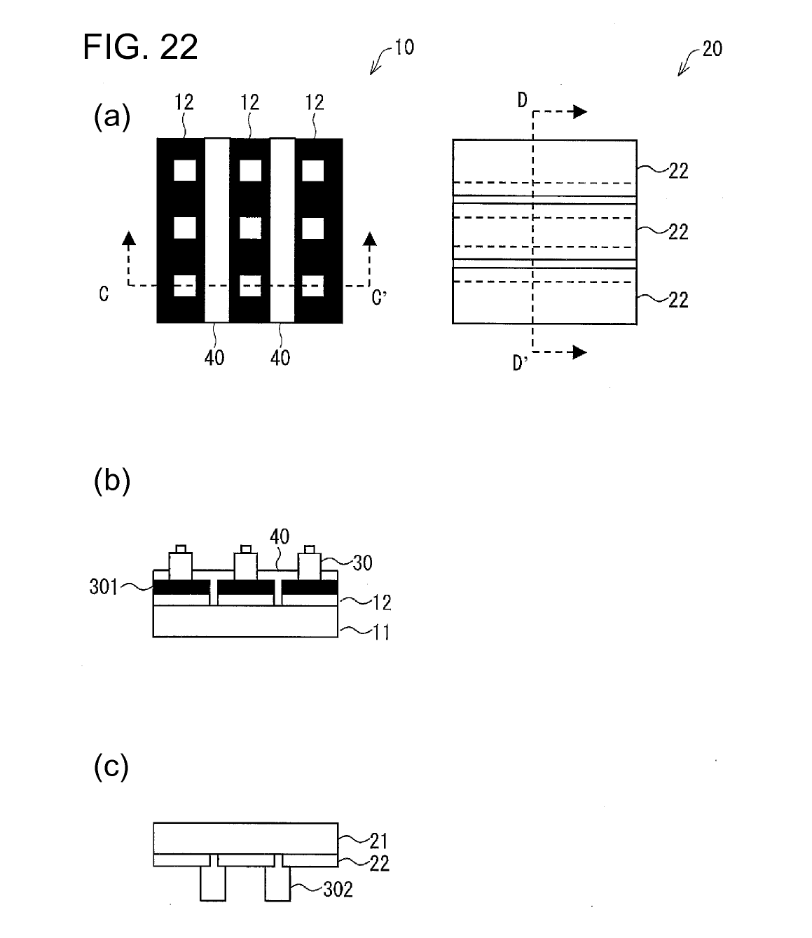

As shown in FIG. 21(a), in the second method, the UV curable resin 41, which has not been cured yet, is first disposed over the first substrate 10 on which the LED elements 30 have been arranged in the step of arranging the LED elements such that the UV curable resin 41 covers the LED elements 30.

Next, as shown in FIG. 21(a), UV light is radiated from the rear of the first substrate 10 to cure the UV curable resin 41.

At this time, the conductive adhesive 301 is non-transparent, and thus, light is not radiated on portions of the UV curable resin 41 over the conductive adhesive 301.

However, UV light enters the area over the periphery of the conductive adhesive 301 obliquely, thereby reaching the area above the periphery of the conductive adhesive 301. The portion of the UV curable resin 41 over the periphery of the conductive adhesive 301 is cured.

Next, the uncured UV curable resin 41 is removed by etching, leaving remaining only the cured portion of the UV curable resin 41, which is the insulating layer 40.

As shown in FIG. 21(b), by the steps above, the insulating layer 40 is formed so as to leave the second element electrode 33 exposed while being provided in the area between adjacent first electrodes 12, the area between adjacent conductive adhesives 301 provided on the first electrodes 12, and over the periphery of the conductive adhesives 301.

(Step of Bonding Substrates)

Next, the step of bonding the substrates will be described.

In the method of manufacturing the display device of the present embodiment, the insulating layer 40 formed in the step of forming the insulating layer, which is the previous step, does not reach the top surface of the LED elements 30.

Thus, when bonding the second substrate 20 to the first substrate 10 by the previously described step of bonding the substrates, only the second element electrodes 33 of the LED elements 30 are in contact with the second substrate 20, and a gap is formed in large portions between the first substrate 10 and the second substrate 20.

In such a case, the bonding strength between the second substrate 20 and the second element electrodes 33 is insufficient for the display unit 300.

To deal with this issue, as shown in FIG. 20(e), a second substrate 20 having a patterned adhesive 302 between the second electrodes 22 is bonded to the first substrate 10 in the step of bonding the substrates in the method of manufacturing the display device of the present embodiment.

This will be described in further detail with reference to FIG. 22.

FIG. 22(a) is a plan view of the first substrate 10 and the second substrate 20 used during the step of bonding the substrates in the method of manufacturing the display device of the present embodiment. FIG. 22(b) is a cross-sectional view of FIG. 22(a) along the line C-C′, and FIG. 22(c) is a cross-sectional view of FIG. 22(a) along the line D-D′.

As shown in FIG. 22(c), patterned adhesives 302 extending along the extension direction of the second electrodes 22 are provided between adjacent second electrodes 22 on the second substrate 20.

The first substrate 10 and the second substrate 20 are bonded together such that the patterned adhesive 302 is disposed between the first substrate 10 and the LED elements 30.

In this manner, the insulating layer 40 of the first substrate 10 and the patterned adhesive 302 on the second substrate 20 are bonded to each other.

In this manner, as shown in FIG. 20(f), it is possible to manufacture the display device of the present embodiment in which adhesive strength between the first substrate 10 and the second substrate 20 is ensured, and in which short-circuiting between first electrodes 12 is prevented.

(Other Configurations)

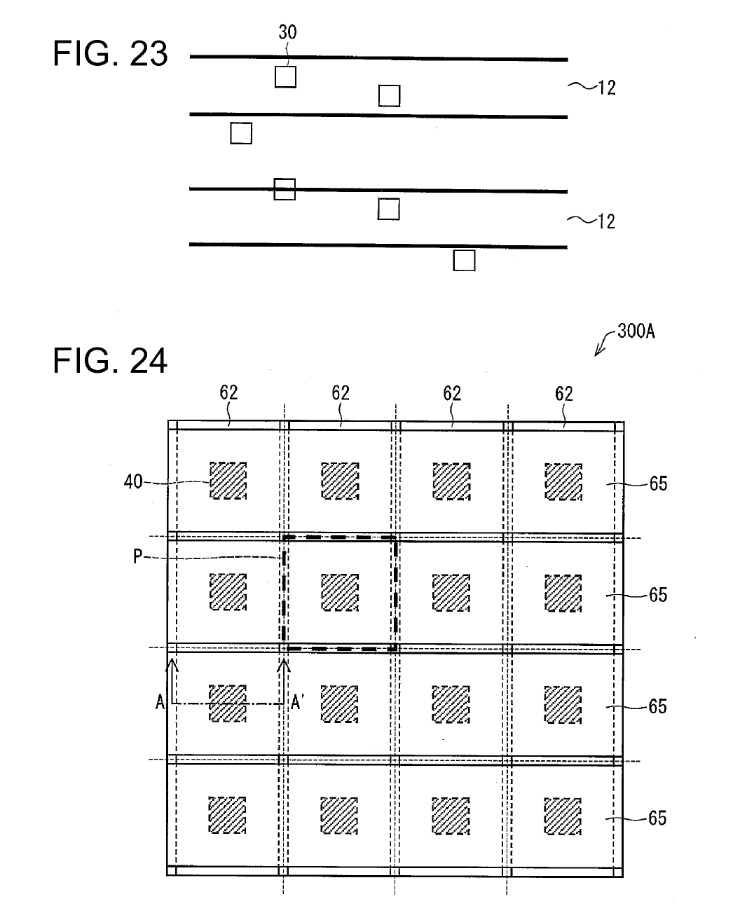

Other characteristic configurations of the display device of the present invention will be described with reference to FIG. 23.

In the step of arranging the LED elements described above, the gaps between adjacent LED elements 30 are adjusted using the dicing tape 6 to match the gaps between adjacent first electrodes 12 provided in a stripe pattern on the first substrate 10 and the gaps between adjacent second electrodes 22 provided in a stripe pattern on the second substrate 20 to mount the LED elements 30 onto the substrate.

However, the following method can also be used as an alternate step of arranging the LED elements of the present invention. The alternate step is a method of arranging (mounting) the LED elements 30 randomly on the first substrate 10.

FIG. 23 is a plan view of the first substrate 10. As shown in FIG. 23, in the display device of the present invention, the gap (slit width) between adjacent first electrodes 12 can be made greater than the width of the electrode surface of the LED element 30.

Thus, the LED element 30 is disposed such that the first element electrode 31 thereof is formed across a plurality of first electrodes 12. In this manner, no matter where on the first substrate 10 the LED element 30 is disposed, no short-circuiting occurs between the plurality of first electrodes 12.

By designing the slit width of the first electrode 12 and the electrode surface width of the LED element 30 in this manner, an excellent display can be attained even if the display device is manufactured by arranging the LED elements 30 randomly on the first substrate 10.

When the LED elements 30 are arranged randomly, the number of LED elements 30 disposed on the first electrodes 12 varies, which can result in uneven luminance. In such a case, an even display can be attained by measuring the actual luminance of the display device and adjusting (correcting) the gradation.

Another problem of the conventional techniques will be described here.

FIG. 42 is a side view showing the configuration of an image display device 400 disclosed in Patent Document 1 as a conventional technique.

The image display device 400 shown in FIG. 42 has lower wiring lines 402 and transparent electrodes 403R, 403G, and 403B formed on a substrate 401, and on the upper surface thereof, light-emitting elements 405R, 405G, and 405B and an insulating layer 408 are formed. Also on the upper surface, upper wiring lines 404R, 404G, and 404B and connecting electrodes 406R, 406G, and 406B integrally formed respectively with the upper wiring lines 404R, 404G, and 404B are formed. The light-emitting surface of the light-emitting elements 405R, 405G, and 405B are electrically connected respectively to the transparent electrodes 403R, 403G, and 403B, and the portions of the light-emitting elements opposite to the light-emitting surfaces are electrically connected respectively to the connecting electrodes 406R, 406G, and 406B. As light-emitting elements 405R, 405G, and 405B, light-emitting diodes (LEDs) are used.

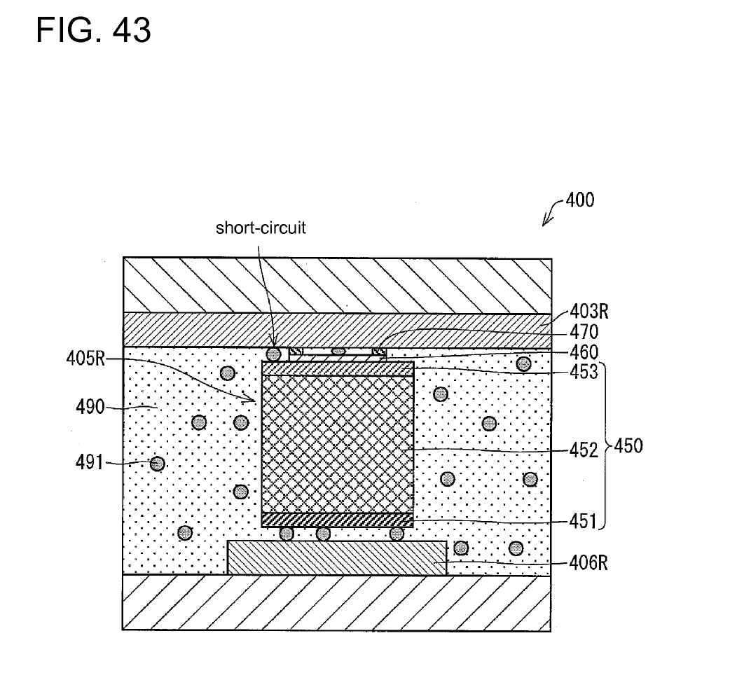

FIG. 43 is a cross-sectional view of a typical light-emitting element that can be used as the light-emitting element 405R of Patent Document 1.

The light-emitting element 405R shown in FIG. 43 includes an upper electrode 470 (second element electrode) electrically connected to a transparent electrode 403R, a lower electrode 450 (first element electrode) electrically connected to a connecting electrode 406R, and a light-emitting portion 460 electrically connected to the upper electrode 470 and the lower electrode 450, the light-emitting portion 460 emitting light by a voltage being applied between the upper electrode 470 and the lower electrode 450.

It is possible to conceive of the light-emitting element 405R being connected respectively to the connecting electrode 406R and the transparent electrode 403R through an anisotropic conductive layer 490. The anisotropic conductive layer 490 is a film in which conductive particles 91 are dispersed in a resin.

The image display device of Patent Document 1 requires a high degree of precision in positioning the respective light-emitting diodes in the step of arranging the light-emitting diodes in a matrix.

This increases the cost, and as a result, it becomes difficult to reduce the cost of the display device.

Here, due to problems in manufacturing, it is difficult to completely cover the top surface of the lower electrode 450 by the light-emitting portion 460 in the light-emitting element 405R. Thus, a portion of the top surface of the lower electrode 450 is an exposed portion that is not in contact with the light-emitting portion 460.

If the light-emitting element 405R is respectively connected to the connecting electrode 406R and the transparent electrode 403R through the anisotropic conductive layer 490, the presence of a conductive particle 91 between the exposed portion of the lower electrode 450 and the transparent electrode 403R results in a short-circuit between the lower electrode 450 and the transparent electrode 403R, which means that it becomes impossible to accurately control the emission of light from the light-emitting element 405R. If the light-emitting element 405R does not emit light as normal, this results in a decrease in display quality in the display device.

One possibility to prevent a short-circuit between the lower electrode 450 and the transparent electrode 403R is to form an insulator on the lower electrode 450, but forming an insulator only on the lower electrode 450 is not easy.

In the manufacturing method, the process of manufacturing an image display device such as that of Patent Document 1 requires a high degree of precision during positioning, and when the method of arranging elements of Patent Document 2 is used as the method of arranging elements on a substrate of the display device, a low number of elements can be arranged per unit time, and thus, the production efficiency is low.

Also, when using the element transfer method of Patent Document 3, there are cases in which the elements cannot be accurately transferred, which reduces the yield.

Below, an embodiment of a display device by which it is possible to accurately control light emitted by light-emitting elements, and a method of manufacturing the display device will be described.

Also, an embodiment relating to a low cost and high resolution display device having light-emitting elements, and a manufacturing method by which it is possible to manufacture this display device at a high efficiency and low cost will be described.

### Embodiment 5

Another embodiment according to the present invention is as described below with reference to FIGS. 24 to 33. For ease of explanation, the members having the same functions as described in the previous embodiments are given the same reference characters, and the descriptions thereof are omitted.

(Display Device)

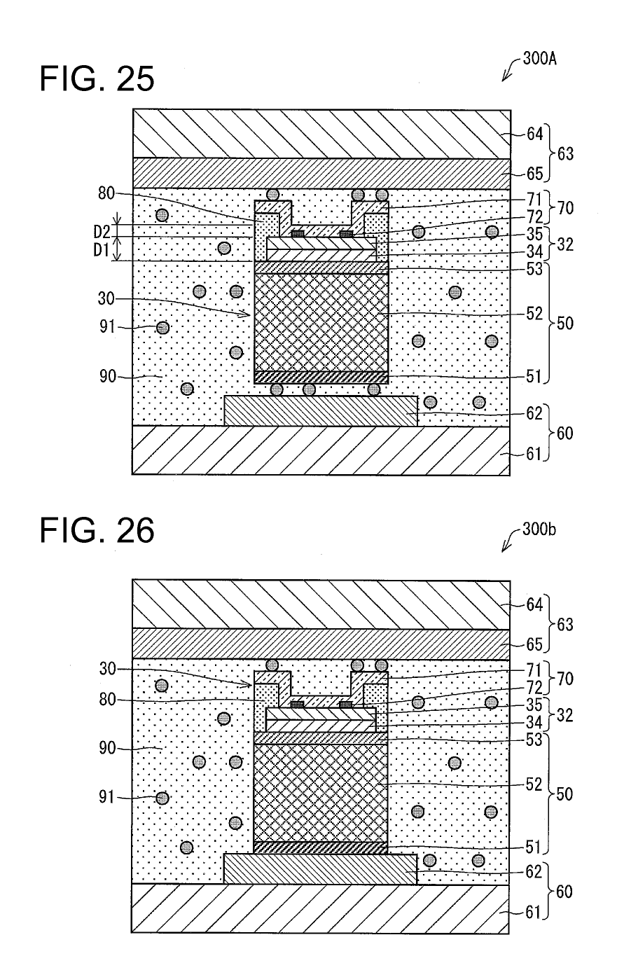

FIG. 24 is a plan view of a display unit 300A of a display device of the present embodiment. FIG. 25 is a cross-sectional view along the line A-A′ of FIG. 24.

As shown in FIG. 25, the display unit 300A of the display device of the present embodiment includes a first substrate 60 and a second substrate 63 disposed to face each other.

The first substrate 60 includes a transparent substrate 61 and first electrodes 62 provided on the transparent substrate 61, and the plurality of first electrodes 62 are arranged in a stripe pattern on the surface of the first substrate 60 facing the second substrate 63.

The second substrate 63 includes a transparent substrate 64 and second electrodes 65 provided on the transparent substrate 64, and the plurality of second electrodes 65 are arranged in a stripe pattern on the surface of the second substrate 63 facing the first substrate 60.

As shown in FIG. 24, the first electrodes 62 and the second electrodes 65 intersect in a plan view. Also, LED elements 30 (light-emitting elements) are provided in areas between the first substrate 60 and the second substrate 63 in regions where the first electrodes 62 and the second electrodes 65 intersect in a plan view (intersections). The display unit 300A of the present embodiment is provided with LED elements 30 at the respective intersections, and in a plan view, pixels P are formed in positions corresponding to where the LED elements 30 are provided.

In an actual display device, pixels P are formed using approximately 6 million LED elements 30, but 16 LED elements 30 are shown in FIG. 24 for description.

Also, as shown in FIG. 25, an anisotropic conductive material 90 is provided to fill the area between the second substrate 63 and the first substrate 60. The LED element 30 is fixed between the first substrate 60 and the second substrate 63 by the anisotropic conductive material 90.

The anisotropic conductive material 90 is formed by dispersing conductive particles 91 (conductive balls) in a resin, and achieve conduction by the conductive particles 91 being in contact with each other. In other words, as shown in FIG. 25, by providing conductive particles 91 between the second electrodes 65 and the LED elements 30, the second electrodes 65 and the LED elements 30 are electrically connected to each other through the conductive particles 91. Similarly, by providing conductive particles 91 between the first electrodes 62 and the LED elements 30, the first electrodes 62 and the LED elements 30 are electrically connected to each other through the conductive particles 91.

The LED element 30, and the second electrode 65 and first electrode 62 need not necessarily be electrically connected through the conductive particles 91. The LED element 30 shown in FIG. 26 is electrically connected to the first electrode 62 by being in direct contact therewith. In this manner, a configuration may be adopted in which the LED element 30 is electrically connected to the electrode provided on the substrate by being in direct contact therewith.

By forming the first substrate 60 and the second substrate 63 of a deformable material, it is possible to make the display device of the present embodiment a flexible display.

In the display device of the present embodiment, the first electrodes 62 and the second electrodes 65 are sequentially selected, and a voltage is applied between selected electrodes. The display device displays images by applying a voltage to the LED element 30 provided at the intersection between a selected first electrode 62 and second electrode 65 such that the LED element 30 emits light.

In other words, the display device of the present embodiment is of a simple matrix type. A control unit used in a conventional simple matrix display device can be used as the control unit for the display device of the present embodiment, and thus, descriptions thereof will be omitted.

(LED Element)

The detailed structure of the LED element 30 of the present embodiment will be described with reference to FIG. 25.

It is possible to use as the LED element 30 of the present embodiment an LED element having an upper electrode 70 (second element electrode) provided on the upper side, a lower electrode 50 (first element electrode) provided on the lower side, and a light-emitting layer 32 (light-emitting portion) provided between the upper electrode 70 and the lower electrode 50. The upper electrode 70 and the lower electrode 50 face each other.

The upper electrode 70 is electrically connected to the second electrode 65, the lower electrode 50 is electrically connected to the first electrode 62, and the light-emitting layer 32 is electrically connected to the upper electrode 70 and the lower electrode 50.

By using LED elements 30 having electrodes on the top surface and the bottom surface, it is possible to mount the LED elements 30 with ease by sandwiching the LED elements 30 between the second substrate 63 and the first substrate 60.

The lower electrode 50 has a structure in which a P electrode 51, a conductor 52, and a barrier metal 53 in contact with the light-emitting layer 32 are layered in that order from the bottom. The center of the upper surface of the lower electrode 50 (upper surface of the barrier metal 53) is covered by the light-emitting layer 32, but the periphery of the upper surface is not covered by the light-emitting layer 32. The portion of the upper surface of the lower electrode 50 not covered by the light-emitting layer 32 is an exposed portion.

The upper electrode 70 has gold electrodes 72 in contact with the light-emitting layer 32 and an N electrode 71 provided to cover the gold electrodes 72. The N electrode 71 is a transparent electrode, the central portion thereof being the contact portion in contact with the light-emitting layer 32, the edge thereof being a non-contact portion that is not in contact with the light-emitting layer 32.

The light-emitting layer 32 has a PN junction between the P-type semiconductor layer 35 and the N-type semiconductor layer 34. When a voltage is applied to the LED element 30, electrons and holes in the light-emitting layer 32 move, and holes in the P-type semiconductor layer 35 and the electrons in the N-type semiconductor layer 34 collide, and bond together. The energy formed by the bonding of the holes and electrons is outputted as light energy.

The exposed portion of the lower electrode 50 and the edge of the light-emitting layer 32 are covered by a transparent insulator 80 (first insulating layer, second insulating layer). The transparent insulator 80 is a few dozen μm in thickness, for example, and it is possible to use an ultraviolet curable resin film or the like as the transparent insulator 80.

The non-contact portion of the N electrode 71 is provided over the lower electrode 50 and the light-emitting layer 32 across the transparent insulator 80.

As a result, the distance between the lower electrode 50 and the second electrode 65 in a direction perpendicular to the surface of the second substrate 63 is greater than the sum of the thickness D1 of the light-emitting layer 32 and the thickness D2 of the upper electrode 70. The thickness D2 of the upper electrode 70 does not refer to the thickness (height) from the top to the bottom of the upper electrode 70 but rather the thickness of the material used in the N electrode 71.

According to the configuration above, it is possible to ensure a sufficient distance between the second electrode 65 and the lower electrode 50 of the LED element 30, which reduces the risk of a short-circuit therebetween.

The transparent insulator 80 is provided between the N electrode 71 and the exposed portion of the lower electrode 50, and thus, no conductive particles 91 enter the space between the N electrode 71 and the lower electrode 50. In other words, the P electrode and the N electrode are not present within a range that allows both to be simultaneously connected to the anisotropic conductive material 90. Thus, it is possible to reduce the risk of short-circuiting between the N electrode 71 and the lower electrode 50.

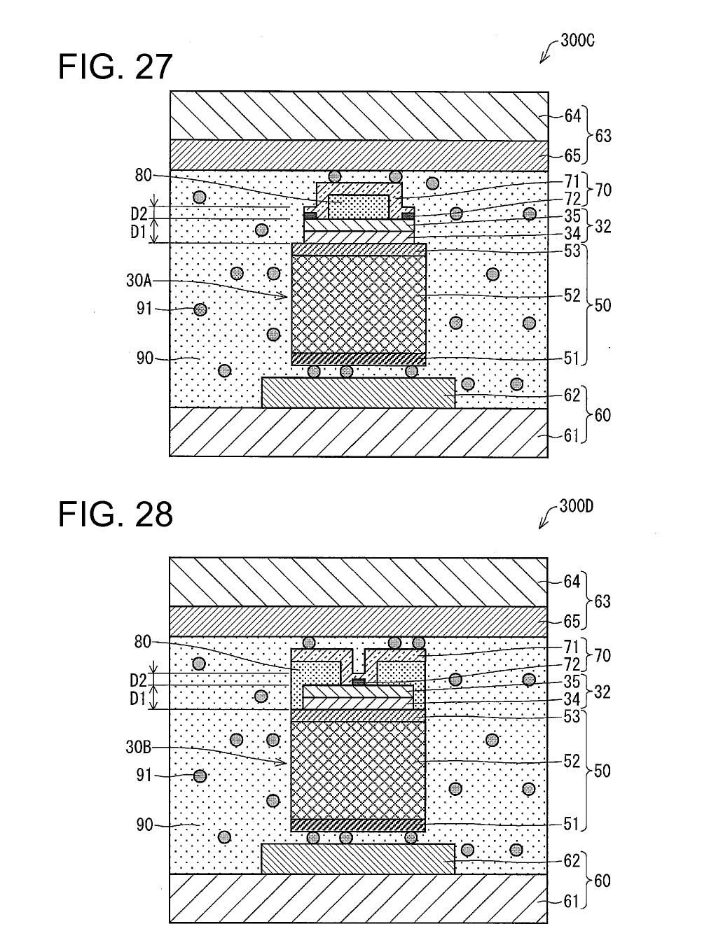

Next, another configuration of an LED element of the present embodiment will be described with reference to FIGS. 27 and 28. The LED elements shown in FIGS. 27 and 28 can be used as the LED element of the present embodiment.

Unlike the LED element 30 shown in FIG. 25, in the LED element 30A of FIG. 27, the exposed portion of the lower electrode 50 and the edge of the light-emitting layer 32 are not covered by the transparent insulator 80. On the other hand, the central portion of the upper surface of the light-emitting layer 32 is covered by the transparent insulator 80.

The gold electrodes 72 are disposed on the edge of the light-emitting layer 32. The edge of the N electrode 71 is the contact portion in contact with the light-emitting layer 32, whereas the central portion of the N electrode 71 is provided over the light-emitting layer 32 across the transparent insulator 80 and is a non-contact portion that is not in contact with the light-emitting layer 32.

Even with the structure of the LED element 30A in FIG. 27, the distance between the lower electrode 50 and the second electrode 65 in a direction perpendicular to the surface of the second substrate 63 can be made greater than the sum of the thickness D1 of the light-emitting layer 32 and the thickness D2 of the upper electrode 70.

Next, an LED element 30B shown in FIG. 28 will be described. The LED element 30B of FIG. 28, unlike the LED element 30 of FIG. 25, has one gold electrode 72 provided on the central portion (that is, the center of the pixel P) of the upper surface of the light-emitting layer 32. The LED element 30B has a larger area of the upper surface of the light-emitting layer 32 covered by the transparent insulator 80 than the LED element 30 shown in FIG. 25.

Thus, according to the LED element 30B of FIG. 28, it is possible to stabilize the connection between the N electrode 71 and the light-emitting layer 32 and lower electrode 50.

In this manner, the LED element 30 of the present embodiment has a structure with a lower risk of short-circuiting, and thus, it is possible to achieve conduction with ease simply by sandwiching the LED element 30 between the upper and lower electrodes respectively provided on the upper and lower substrates.

(Method of Manufacturing Display Device)

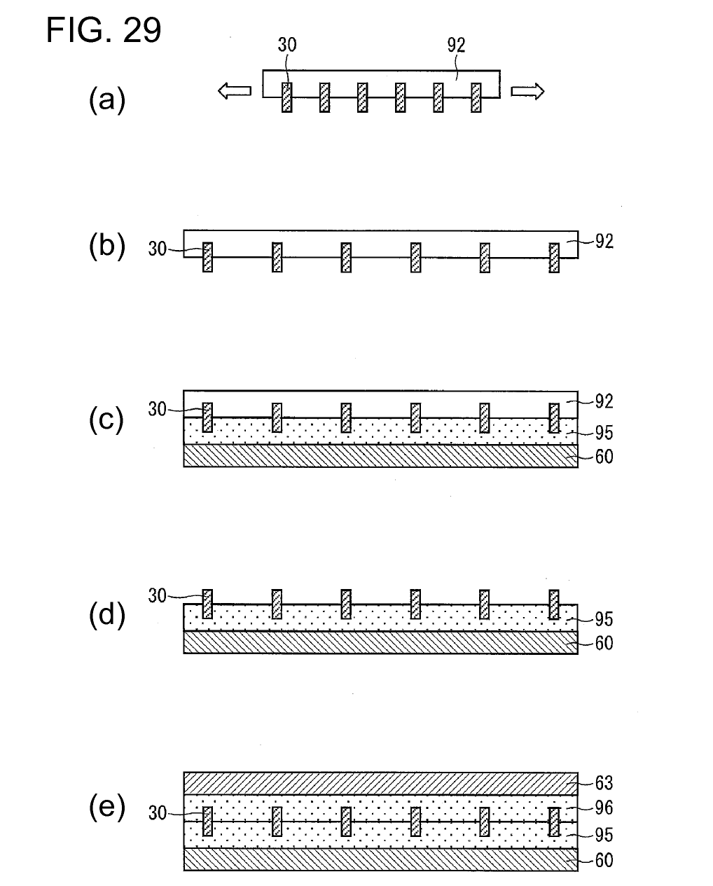

A preferred method of manufacturing the display device of the present embodiment will be described with reference to FIGS. 29 to 33.

As described above, the display unit 300A of the display device of the present embodiment has the LED element 30 fixed between the first substrate 60 and the second substrate 63 by the anisotropic conductive material 90. More specifically, the upper surface of the LED element 30 is connected to the second substrate 63 through the anisotropic conductive material 90, and the lower surface is connected to the first substrate 60 through the anisotropic conductive material 90.

In general, a method is adopted in which the LED element 30 is formed by first forming one LED, and dicing the LED to obtain a plurality of LED elements 30 simultaneously.

When forming a plurality of LED elements 30 by such a method, it is necessary to mount the LED elements 30 in prescribed positions after adjusting the gaps between adjacent LED elements 30. In other words, the gaps between the LED elements 30 are adjusted to match the gaps between the first and second electrodes provided in a stripe pattern on the substrate, and then mounted on the electrodes.

When mounting the LED elements 30 on the substrate as in the display device of the present embodiment, in general, a method is used in which the LED elements 30 are picked up by a transfer film to transfer the LED elements 30 onto the substrate.

The method of mounting the LED elements 30 onto the substrate using the transfer film will be described with reference to FIG. 29. FIG. 29 is a drawing for describing a method of manufacturing a display device as a reference example.

First, in a state in which the LED elements 30 are picked up by a transfer film 92 (FIG. 29(a)), the transfer film 92 is stretched to adjust the gap between the LED elements 30 (FIG. 29(b)).

Next, the transfer film 92 is bonded to the first anisotropic conductive film 95 (ACF) provisionally bonded to the first substrate 60, thereby disposing the LED elements 30 onto the first anisotropic conductive film 95 (FIG. 29(c)). At this time, the transfer film 92 is bonded onto the first anisotropic conductive film 95 such that the LED elements 30 are disposed over the first electrodes 62 (not shown).

Next, the transfer film 92 is peeled from the first anisotropic conductive film 95 (FIG. 29(d)).

Next, a second anisotropic conductive film 96 provisionally bonded onto the second substrate 63 is bonded onto the first anisotropic conductive film 95 so as to cover the LED elements 30 not covered by the first anisotropic conductive film 95 (FIG. 29(e)). At this time, the second anisotropic conductive film 96 is bonded to the first anisotropic conductive film 95 such that the LED elements 30 are disposed at intersections in a plan view between the second electrodes 65 (not shown) and the first electrodes 62 (not shown).

Next, the first and second anisotropic conductive films 95 and 96 are thermocompression bonded respectively to the second substrate 63 and the first substrate 60. More specifically, pressure is applied between the second substrate 63 and the first substrate 60 in a state in which the first and second anisotropic conductive films 95 and 96 are sandwiched between the second substrate 63 and the first substrate 60 to pressure bond the first and second anisotropic conductive films 95 and 96 to the first and second substrates 60 and 63.

The pressure bonded first and second anisotropic conductive films 95 and 96 constitute the anisotropic conductive material 90 described with reference to FIG. 25 and the like.

In this manner, it is possible to manufacture the display device of the present embodiment. However, if the LED elements 30 are mounted in this manner, this decreases the yield due to transfer defects occurring during the step of transferring the LED elements 30 from the transfer film 92 to the first anisotropic conductive film 95.

A method of mounting the LED elements 30 without the need for a transfer step is adopted as the method of manufacturing the display device of the present embodiment.

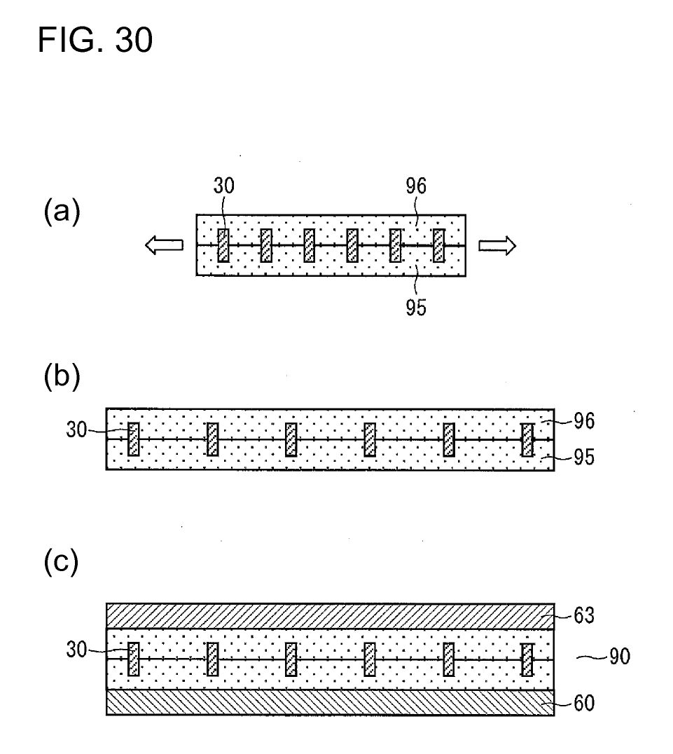

A method of manufacturing the display device of the present embodiment will be described with reference to FIG. 30. FIG. 30 is a drawing for describing a method of manufacturing a display device.

As shown in FIG. 30, in the method of manufacturing the display device of the present embodiment, the LED elements 30 are sandwiched between the first anisotropic conductive film 95 (first film) and the second anisotropic conductive film 96 (second film). The first anisotropic conductive film 95 and the second anisotropic conductive film 96 have an increased concentration of conductive particles compared to commercially available anisotropic conductive films.

Next, the first and second anisotropic conductive films 95 and 96 are stretched to adjust the gaps between adjacent LED elements 30 (FIGS. 30(a) and 30(b)).

Next, the first and second anisotropic conductive films 95 and 96 are sandwiched between the second substrate 63 and the first substrate 60 and then thermocompression bonded (FIG. 30(c)). At this time, the first and second anisotropic conductive films 95 and 96 are thermocompression bonded to the second substrate 63 and the first substrate 60 such that the LED elements 30 are disposed at the intersections between the second electrodes 65 and the first electrodes 62.

By thermocompression bonding, the conductive particles 91 included in the first and second anisotropic conductive films 95 and 96 are crushed between the LED elements 30 and the first and second electrodes 62 and 65, thereby electrically connecting the electrodes on the LED elements 30 to the first and second electrodes 62 and 65.

It is preferable that the first and second anisotropic conductive films 95 and 96 have a high degree of transparency, and are a type of film that does not change color due to thermocompression bonding.

In this manner, it is possible to manufacture the display device of the present embodiment.

In the manufacturing method described above, the first and second anisotropic conductive films 95 and 96 are stretched with the LED elements 30 sandwiched therebetween, and the LED elements 30 are mounted onto the substrates together with the first and second anisotropic conductive films 95 and 96.

In other words, according the manufacturing method above, the gaps between the LED elements 30 are adjusted and the LED elements 30 are bonded to the substrates by the first and second anisotropic conductive films 95 and 96.

According to the method of manufacturing the display device of the present embodiment, the transfer step is unnecessary, and thus, a decrease in yield due to transfer defects does not occur. In the manufacturing method using the transfer film 92, the transfer film 92 is disposed after used, but according to the manufacturing method described above, the transfer film 92 is not needed, and thus, it is possible to manufacture the display device of the present embodiment at a low cost.

(Concentration of Conductive Particles)

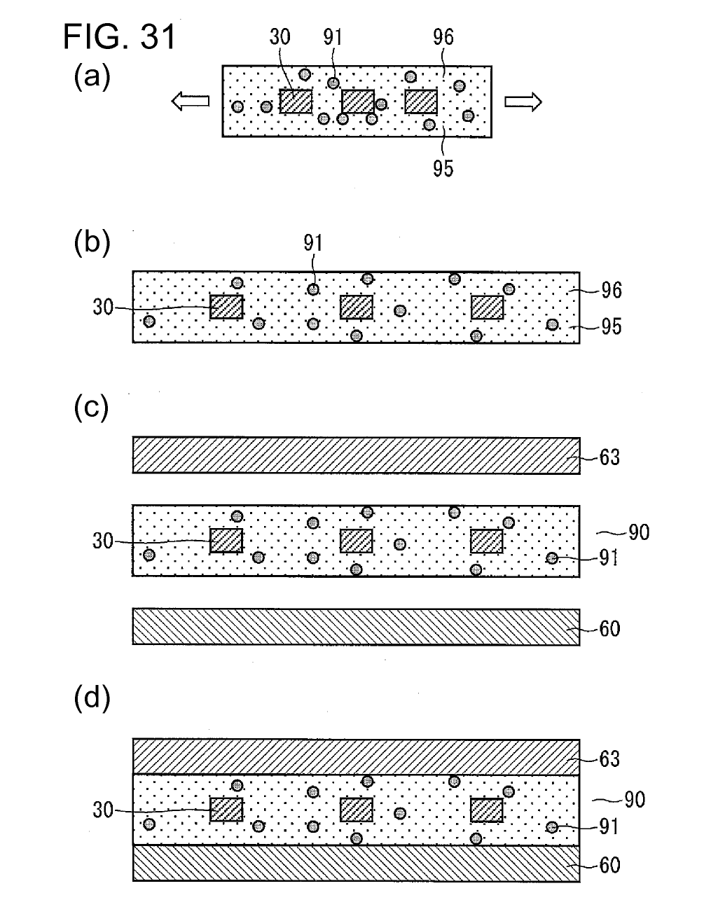

FIG. 31 corresponds to FIG. 30 and is a drawing for describing in further detail the method of manufacturing the display device of the present embodiment while depicting the conductive particles 91.

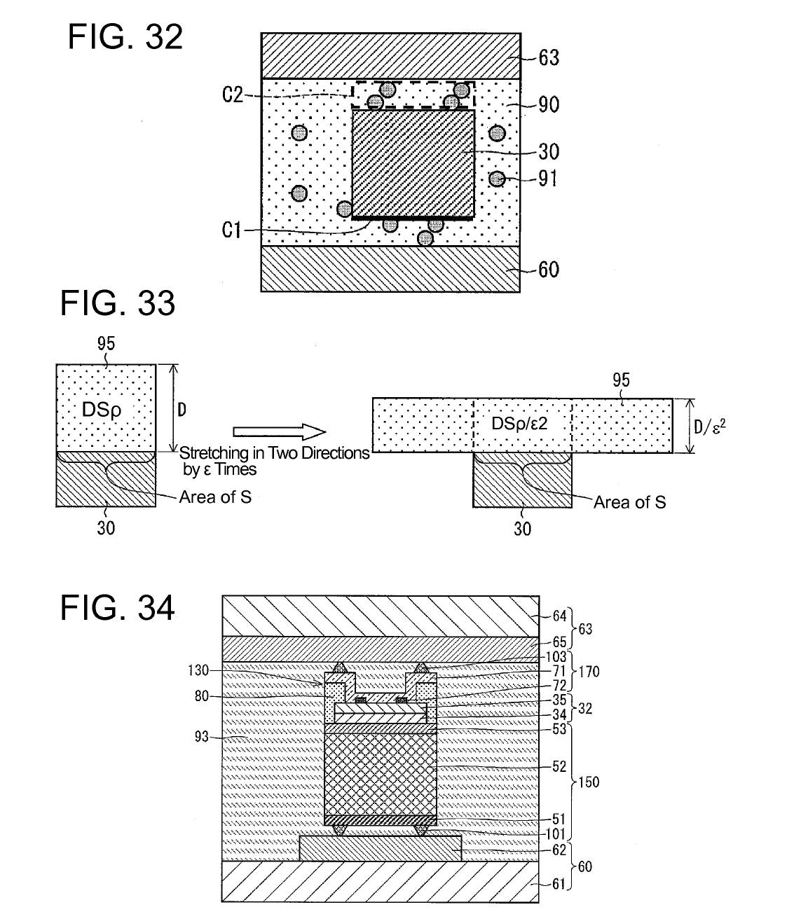

FIG. 32 is a cross-sectional view of the display unit of the present embodiment obtained by the manufacturing method shown in FIG. 31.

As shown in FIG. 32, the LED elements 30 are electrically connected to the electrodes (not shown) provided on the second substrate 63 and the first substrate 60 through the anisotropic conductive material 90.

The electrical connection is ensured by the portion of the anisotropic conductive material 90 overlapping the electrodes on the LED elements 30 when viewing the display unit in a plan view. In the description below, the portion of the LED element 30 in contact with the anisotropic conductive material 90 is a contact surface C1. The portion of the anisotropic conductive material 90 overlapping the LED element 30 is a conduction-contributing region C2.

As shown in FIG. 31, when the first and second anisotropic conductive films 95 and 96 are stretched with the LED elements 30 sandwiched therebetween, the stretching results in the concentration in the horizontal direction and the vertical direction of conductive particles 91 included in the first and second anisotropic conductive films 95 and 96 for the LED elements 30 to change.

Also, in FIG. 31, the first and second anisotropic conductive films 95 and 96 are stretched in a direction parallel to the electrode surfaces of the LED elements 30 (horizontal direction), resulting in a reduction in the number of conductive particles 91 included in the conduction-contributing region C2.

When the number of conductive particles 91 in the conduction-contributing region C2 decreases, there is a risk that conduction between the LED element 30 and the first and second electrodes provided on the substrate cannot be ensured.

The concentration of conductive particles 91 in the first and second anisotropic conductive films 95 and 96 prior to stretching is determined while taking into consideration the decrease in the number of conductive particles 91 in the conduction-contributing region C2 due to the stretching of the first and second anisotropic conductive films 95 and 96.

Below, a detailed description will be made with reference to FIG. 33. FIG. 33 is a schematic view for describing a change in concentration of conductive particles 91 in the conduction-contributing region C2 before and after the first anisotropic conductive film 95 has been stretched.

A hypothetical situation will be considered in which the first anisotropic conductive film 95, which has a thickness of D and a concentration of conductive particles 91 therein of ρ, is stretched in two directions perpendicular to each other while being parallel to the contact surface C1 with the LED element 30, the contact surface C1 having an area of S, thereby increasing the dimensions of the first anisotropic conductive film 95 in the two directions by ε times.

The number of conductive particles 91 included in the conduction-contributing region C2 of the first anisotropic conductive film 95 prior to stretching is expressed as D×S×ρ.

The number of conductive particles 91 included in the conduction-contributing region C2 of the first anisotropic conductive film 95 after stretching is expressed as D×S×ρ/ε².

Taking into consideration the change in number of conductive particles 91 in the conduction-contributing region C2 due to the stretching of the first anisotropic conductive film 95, the corresponding minimum connecting area is determined. The corresponding minimum connecting area is the area of the surfaces of conductors facing each other required in order to be able to accommodate three or more particles at an average of −4.5σ. In other words, the corresponding minimum connecting area is the minimum area for the contact surface C1 required in order for the LED element 30 to be electrically connected to the second electrode through the first anisotropic conductive film 95, which includes a certain number (concentration) of conductive particles 91.

Where the corresponding minimum connecting area of the first anisotropic conductive film 95 prior to stretching is S0, the corresponding minimum connecting area S1 of the first anisotropic conductive film 95 after stretching is

S1=ε²×S0.

Thus, if the area of the contact surface C1 is S, then the corresponding minimum connecting area S0 prior to stretching of the first anisotropic conductive film 95, which can be used in the present embodiment, must satisfy the following inequality:

S0<S/ε².

By determining the corresponding minimum connecting area in this manner, the LED element 30 can be electrically connected to the second electrode through the first anisotropic conductive film 95 after stretching thereof.

### Embodiment 6

Another embodiment according to the present invention is as described below with reference to FIGS. 34 to 37. For ease of explanation, the members having the same functions as in drawings described in the previous embodiments are given the same reference characters, and the descriptions thereof are omitted.

FIG. 34 is a cross-sectional view of a display unit 300E of a display device of the present embodiment and corresponds to FIG. 25.

As shown in FIG. 34, the display device of the present embodiment differs from the display device of Embodiment 5 in that conductive protrusions 103 (conductors) are provided respectively on the surfaces of the lower electrode 150 and the upper electrode 170 of the LED element 30. Also, unlike the display device of Embodiment 5, an insulating resin layer 93 fills the area between the second substrate 63 and the first substrate 60. An acrylic resin or an epoxy resin can be used for the insulating resin layer 93, for example.

By the conductive protrusions 103 on the upper electrode 170 side being in contact with the second electrode 65, the upper electrode 170 is electrically connected to the second electrode 65, and by the conductive protrusions 103 on the lower electrode 150 side being in contact with the first electrode 62, the lower electrode 150 is electrically connected to the first electrode 62.

Electrical connection between the LED element 130 and the first and second electrodes 62 and 65 is ensured by the conductive protrusions 103, and there is no need to provide an anisotropic conductive material 90 between the LED element 130 and the second substrate 63 and first substrate 60. Thus, in the display device of the present embodiment, an insulating resin layer 93, instead of the anisotropic conductive material 90, fills the area between the first substrate 60 and the second substrate 63. Therefore, it is possible to provide a display device at a lower cost than the display device of the display device of Embodiment 5.

The conductive protrusions 103 can be made of gold, nickel, or resin coated in gold or nickel, for example. In FIG. 34, the conductive protrusions 103 are conical in shape (with a triangular cross-section), but the shape is not limited thereto. The shape can be a pyramid, a rectangular cuboid, a sphere, a hemisphere, or the like, for example.

Also, in the display device of Embodiment 5, the LED element 30 is electrically connected to the first and second electrodes 62 and 65 through the anisotropic conductive material 90, which has conductive particles 91 randomly dispersed therein. By contrast, in the display device of the present embodiment, the LED element 130 and the first and second electrodes 62 and 65 are electrically connected to each other through conductive protrusions 103 fixed on the surfaces of the upper electrode 170 and the lower electrode 150. Thus, it is possible to electrically connect the LED element 130 to the first and second electrodes 62 and 65 more reliably.

Also, even if the structure of the LED element 130 is not as optimal as the LED element 30 of Embodiment 5, mounting by bonding is possible by determining in advance the positions of the conductive protrusions 103.

Furthermore, the insulating resin layer 93 does not include particles to scatter light such as conductive particles 91, and thus, the display device of the present embodiment has a greater degree of transparency than the display device of Embodiment 5.

(Method of Manufacturing Display Device)

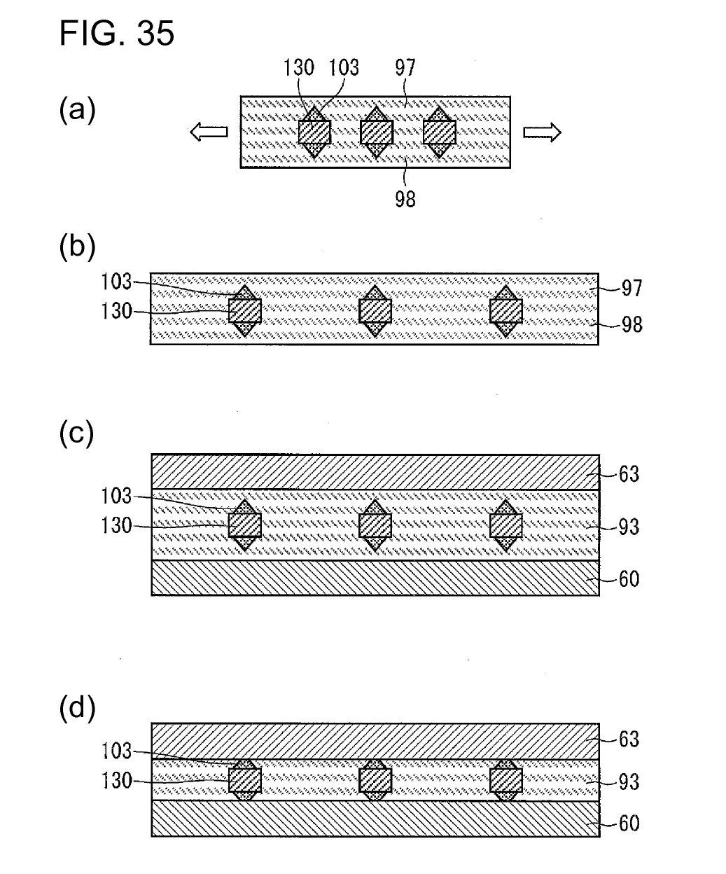

Next a method of manufacturing the display device of the present embodiment will be described with reference to FIG. 35. FIG. 35 is a drawing for describing a method of manufacturing a display device.

The display device of the present embodiment can be manufactured by steps that are similar overall to those of Embodiment 5. First, the LED element 130 having conductive protrusions 103 is sandwiched between two insulating resin films 97 and 98 (FIG. 35(a)).

Next, the insulating resin films 97 and 98 are stretched to adjust the gaps between adjacent LED elements 130 (FIG. 35(b)).

Next, the insulating resin films 97 and 98 are sandwiched between the second substrate 63 and the first substrate 60 and then thermocompression bonded (FIG. 35(c)). At this time, the insulating resin films 97 and 98 are thermocompression bonded to the second substrate 63 and the first substrate 60 such that the LED elements 130 are disposed at the intersections between the first electrode and the second electrodes (not shown).

By thermocompression bonding the insulating resin films 97 and 98 to the second substrate 63 and the first substrate 60, the conductive protrusions 103 penetrate through (protrude from) the insulating resin films 97 and 98. As a result, the conductive protrusions 103 come into contact with the first and second electrodes. Additionally, the conductive protrusions 103 deform under pressure from the second substrate 63 and the first substrate 60 (FIG. 35(d)). The insulating resin films 97 and 98 constitute the insulating resin layer 93 shown in FIG. 34.

By the steps above, it is possible to manufacture the display device of the present embodiment.

In the manufacturing method above, the insulating resin films 97 and 98 are stretched with the LED elements 130 sandwiched therebetween, and the LED elements 130 are mounted together with the insulating resin films 97 and 98 onto the substrates.

According to the method of manufacturing the display device of the present embodiment, the transfer step is unnecessary, and thus, a decrease in yield due to transfer defects does not occur. Furthermore, because a transfer film is not needed, it is possible to manufacture the display device of the present embodiment at a low cost.

The surfaces of the conductive protrusions 103 may be coated such that the surface energy of the conductive protrusions 103 differs from the surface energy of the melted insulating resin films 97 and 98.

For example, the surface of the conductive protrusion 103 can be fluorine-coated. This causes the conductive protrusion 103 to repel the insulating resin films 97 and 98 when they are melted.

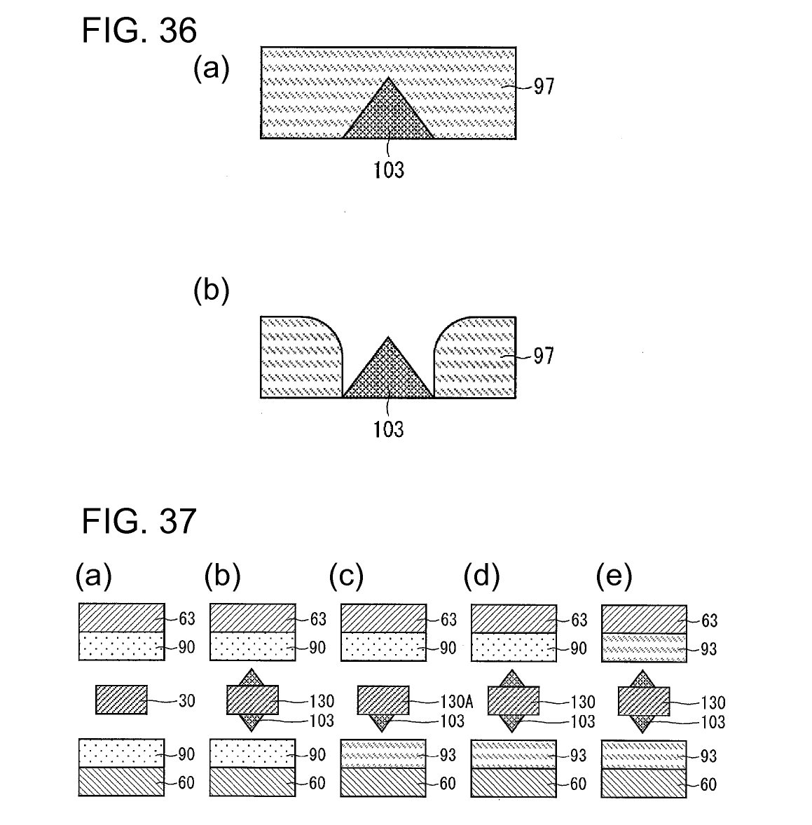

FIG. 36 is a drawing showing the relation between the conductive protrusions 103 and the insulating resin film 97 when the surfaces of the conductive protrusions 103 are fluorine-coated.

FIG. 36(a) shows a state in which the insulating resin film 97 has not been melted. By heating the insulating resin film 97 during thermocompression bonding of the insulating resin film 97 and the second substrate, the insulating resin film 97 is melted.

At this time, the surface of the conductive protrusion 103 is fluorine-coated, and thus, as shown in FIG. 36(b), the melted insulating resin film 97 is repelled from the surface of the conductive protrusion 103, leaving the tip of the conductive protrusion 103 exposed.

As a result, it is possible to connect the conductive protrusions 103 to the second electrodes provided on the second substrate more reliably, thereby ensuring conduction therebetween.

(Other Configurations)

In the display device of the present embodiment, it is possible to use the LED elements 130 having the conductive protrusions 103 and to fill the area between the second substrate and the first substrate with the anisotropic conductive material 90. Also, it is possible to form the conductive protrusions 103 on only one of the electrodes of the LED element 130.

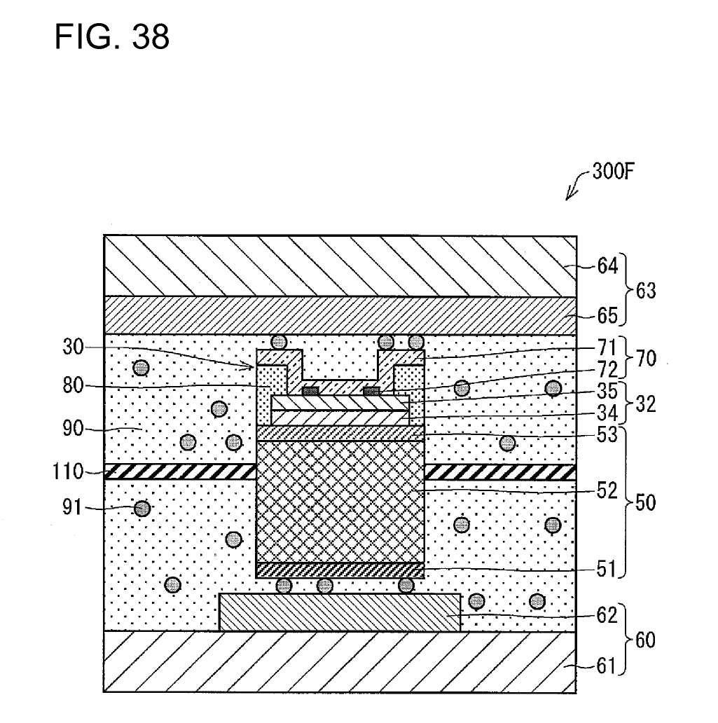

Usable configurations among various configurations combining the presence or lack of conductive protrusions 103 and the material filling the area between the second substrate and the first substrate are shown in FIG. 37 for the display device of Embodiment 5 and the display device of Embodiment 6.

FIG. 37(a) is the configuration of Embodiment 5. That is, conductive protrusions 103 are not provided on the LED element 30 and an anisotropic conductive material 90 fills the area between the second substrate 63 and the first substrate 60.

In FIG. 37(b), conductive protrusions 103 are provided on the LED element 130 and an anisotropic conductive material 90 fills the area between the second substrate 63 and the first substrate 60. Even with this configuration, it is possible to ensure conduction between the LED element 130 and the first and second electrodes.

FIG. 37(c) shows a configuration in which the conductive protrusion 103 is provided only on the lower electrode of the LED element 130A, and of the areas between the second substrate 63 and the first substrate 60, the lower area is filled with the insulating resin layer 93 and the upper area is filled with the anisotropic conductive material 90. Even with this configuration, it is possible to ensure conduction between the LED element 130A and the first and second electrodes.

FIG. 37(d) shows a configuration in which the conductive protrusions 103 are provided on the LED element 130, and of the areas between the second substrate 63 and the first substrate 60, the lower area is filled with the insulating resin layer 93 and the upper area is filled with the anisotropic conductive material 90. Even with this configuration, it is possible to ensure conduction between the LED element 130 and the first and second electrodes.

FIG. 37(e) is the configuration of Embodiment 6. That is, conductive protrusions 103 are provided on the LED element 130 and an insulating resin layer 93 fills the area between the second substrate 63 and the first substrate 60.

### Embodiment 7

Another embodiment according to the present invention is as described below with reference to FIGS. 38 to 40. For ease of explanation, the members having the same functions as in drawings described in the previous embodiments are given the same reference characters, and the descriptions thereof are omitted.

FIG. 38 is a cross-sectional view of a display unit 300F of a display device of the present embodiment and corresponds to FIG. 25.

As shown in FIG. 38 the display device of the present embodiment differs from the display device of Embodiment 5 in that an insulating material layer 110 is provided to divide the anisotropic conductive material 90 into two regions: an upper region and a lower region.

If a conductive impurity or the like enters the anisotropic conductive material 90, this can result in conduction in areas other than the conduction-contributing regions C2 at the LED elements 30. Also, if the anisotropic conductive material 90 deforms during manufacturing and portions where the LED elements 30 are not provided receive pressure, this results in conduction occurring in the portions receiving the pressure.

This results in a short-circuit between the first electrode 62 and the second electrode 65, which results in an inability to control the display.

By contrast, the display device of the present embodiment is provided with the insulating material layer 110 to divide the anisotropic conductive material 90 into two regions including an upper region and a lower region, and thus, the first electrodes 62 can be reliably insulated from the second electrodes 65.

The insulating material layer 110 need not completely separate the anisotropic conductive material 90 into two regions. That is, there may be gaps in the anisotropic conductive material 90 communicating between the region towards the second substrate 63 and the region towards the first substrate 60.

In the display device of the present embodiment, the insulating material layer 110 is formed by dispersing glass spacers therein.

(Method of Manufacturing Display Device)

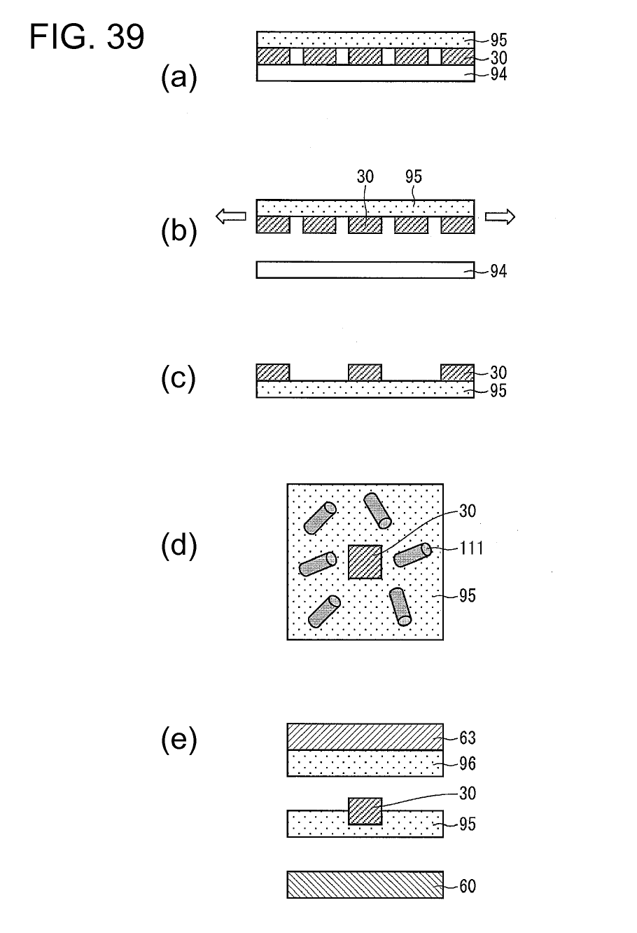

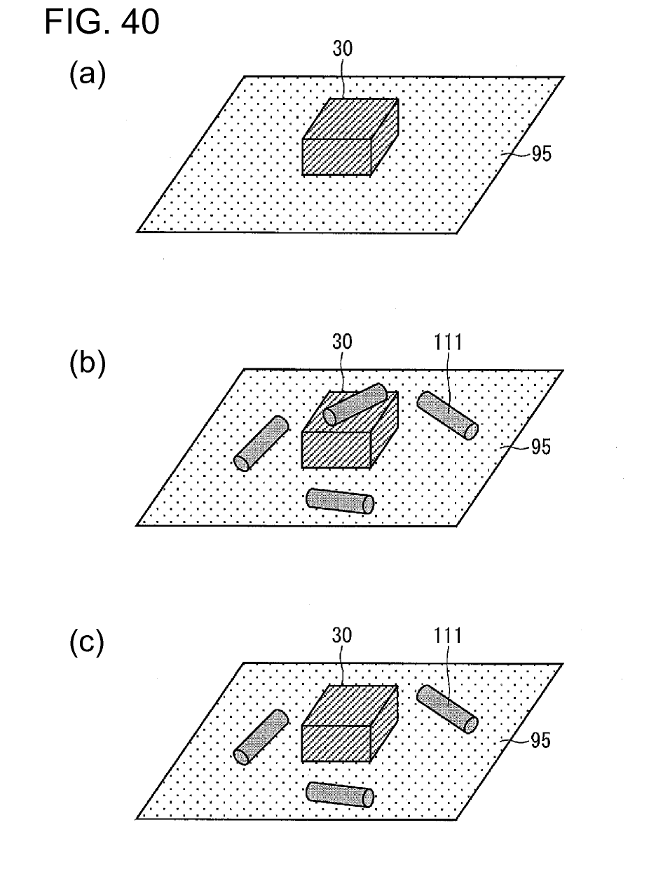

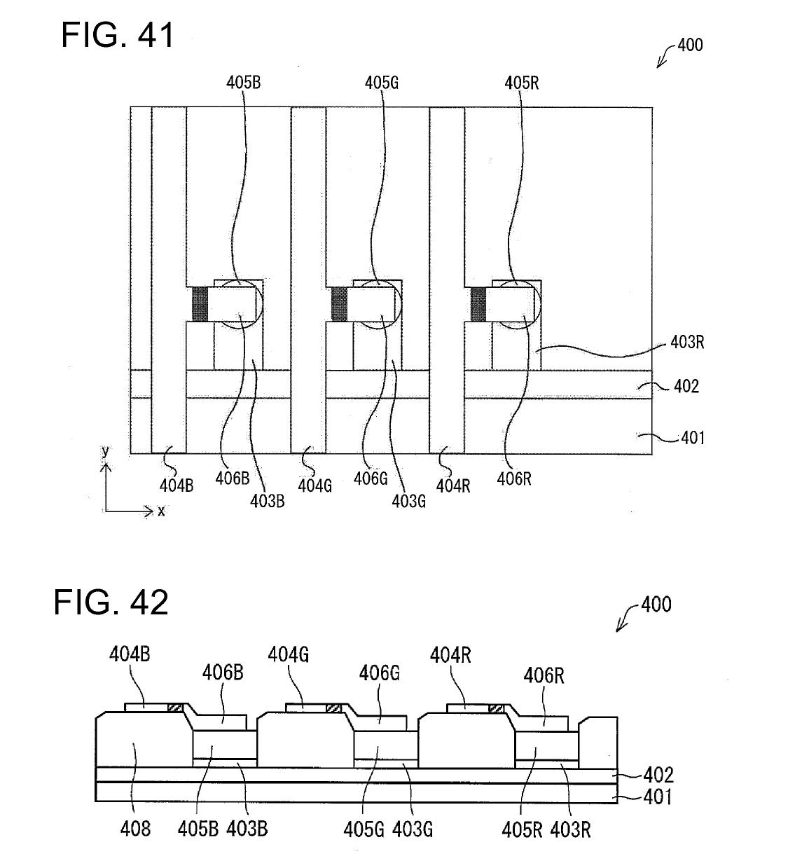

Next a method of manufacturing the display device of the present embodiment will be described with reference to FIG. 39. FIG. 39 is a drawing for describing a method of manufacturing a display device.

First, using the first anisotropic conductive film 95, the LED elements 30 are picked up from a wafer holder 94.

Next, the first anisotropic conductive film 95 is stretched to adjust the gaps between adjacent LED elements 30 (FIG. 39(c)). At this time, a film that does not adhere to the LED elements 30 may cover the LED elements 30 in order to protect the LED elements 30.

Next, glass spacers 111 are dispersed on the surface of the first anisotropic conductive film 95 where the LED elements 30 are provided (FIG. 39(d)).

Next, the second anisotropic conductive film 96 is bonded to the first anisotropic conductive film 95 so as to sandwich the LED element 30 with the first anisotropic conductive film 95. Next, the first and second anisotropic conductive films 95 and 96 are thermocompression bonded by the second substrate 63 and the first substrate 60 (FIG. 39(e)).

By the steps above, it is possible to manufacture the display device of the present embodiment.

The step of dispersing the glass spacers 111 is described in more detail below.

FIG. 40 is a drawing for describing steps of dispersing the glass spacers 111.

In the state shown in FIG. 40(a) in which the LED elements 30 are arranged on the surface of the first anisotropic conductive film 95, the glass spacers 111 are randomly dispersed on the first anisotropic conductive film 95 as shown in FIG. 40(b).

At this time, the first anisotropic conductive film 95 has adhesive (bonding) properties, and thus, the glass spacers 111 dispersed on the first anisotropic conductive film 95 are attached thereto. On the other hand, the glass spacers 111 dispersed onto the LED elements 30 are not attached thereto.

By blowing pressurized air towards the LED elements 30, the glass spacers 111 are blown away and removed from the LED elements 30 by wind pressure.

The glass spacers 111 dispersed on the first anisotropic conductive film 95 are attached to the first anisotropic conductive film 95, and are therefore not blown away by the pressurized air.

In this manner, as shown in FIG. 40(c), the glass spacers 111 can be disposed on only the first anisotropic conductive film 95.

Cylindrical or columnar glass spacers 111 having a diameter less than or equal to the thickness of the LED elements 30 are used in the manufacturing method above.

According to the manufacturing method, the first anisotropic conductive film 95 is stretched in a state in which the LED elements 30 are held on one surface of the first anisotropic conductive film 95, and then, the second anisotropic conductive film 96 is bonded thereto. Thus, the second anisotropic conductive film 96 need not be a stretchable film. Thus, it is possible to use an inexpensive second anisotropic conductive film 96 or an anisotropic conductive paste (ACP).

<Summary>

Also, a display device according to one aspect of the present invention includes: a first substrate including a plurality of first electrodes; a second substrate including a plurality of second electrodes and disposed to face the first substrate; and light-emitting elements that emit light by a voltage being applied thereto, wherein the first electrodes and the second electrodes are arranged in stripe patterns such that the first electrodes extend in a direction differing from a direction in which the second electrodes extend, wherein the light-emitting elements are provided in areas between the first substrate and the second substrate in intersecting regions, the intersecting regions being regions where the first electrodes and the second electrodes intersect in a plan view, and wherein the light-emitting elements respectively include first element electrodes provided on bottom surfaces of the light-emitting elements and electrically connected respectively to the first electrodes, and second element electrodes provided on top surfaces of the light-emitting elements and electrically connected respectively to the second electrodes.

According to the configuration above, it is possible to arrange the light-emitting elements on the substrate without the need for high positional accuracy.

Also, by arranging the light-emitting elements at the intersecting regions of the electrodes, it is possible to arrange many light-emitting elements in a display surface of a certain area.

As a result, it is possible to provide a low cost and high resolution display device having light-emitting elements.

Each of the first electrodes may be provided with a first adhesive layer thereon, each of the light-emitting elements may be fixed onto the first electrodes through the first adhesive layer, and the first element electrodes may be electrically connected respectively to the first electrodes through the first adhesive layer.

According to the configuration above, it is possible to form a reliable electrical connection between the first element electrodes and the first electrodes.

The first electrodes may each have an exposed portion not covered by the first adhesive layer.

The first adhesive layer sometimes includes metal in order to ensure an electrical connection between the first electrodes and the first element electrodes, and thus, the transmittance thereof is not high. However, according to this configuration, the area in a plan view where the first adhesive layer is not provided increases, which allows for a transparent display to be realized.

A width of the exposed portion may be less than a width of the first element electrode.

According to the configuration above, regardless of where on the first electrodes the light-emitting elements are provided, it is possible to fix the light-emitting elements onto the first electrodes across the first adhesive layer and ensure conduction between the first element electrodes and the first electrodes.

The first substrate may include a transparent substrate, the first adhesive layer may be provided on the transparent substrate so as to cover the first electrodes, the first adhesive layer may electrically connect the first element electrodes to the first electrodes by being conductive in a direction perpendicular to a surface of the first substrate, and the first adhesive layer may insulate the adjacent first electrodes from each other by not being conductive in a direction parallel to the surface of the first substrate.

The first adhesive layer may be provided over the entire surface of the transparent substrate because the first adhesive layer is not conductive in the direction parallel to the substrate surface. Thus, it is possible to provide a display device in which the step of disposing the first adhesive layer is simplified.

Each of the second electrodes may be provided with a second adhesive layer thereon, each of the light-emitting elements may be fixed onto the second electrodes through the second adhesive layer, and the second element electrodes may be electrically connected respectively to the second electrodes through the second adhesive layer.

The first adhesive layer may be bonded to the second adhesive layer in at least a portion of an area between the first substrate and the second substrate other than the intersecting regions.

According to the configuration above, a stronger connection can be formed between the first substrate and the second substrate.

An insulating layer may be provided in an area between the first substrate and the second substrate.

According to the configuration above, a short-circuit between the first electrode and the second electrode can be prevented.

The first substrate and the second substrate may be bonded to each other by the insulating layer.

According to the configuration above, the first substrate and the second substrate can be fixed to each other. Also, it is possible to form a reliable (stable) electrical connection between the second element electrodes and the second electrodes.

The insulating layer may be disposed to reach a surface of each of the light-emitting elements facing the second substrate.

The second element electrodes may protrude from a surface of each of the light-emitting elements facing the second substrate, and the insulating layer may be disposed to reach a periphery of each of the second element electrodes.

According to the configuration above, it is possible to cover the surfaces of the light-emitting elements by the insulating layer. Thus, it is possible to prevent short-circuiting in the light-emitting element resulting from the conductor coming into contact with the surface of the light-emitting element. Also, it is possible to bond the second substrate to the first substrate and the light-emitting elements without the use of a second adhesive layer by using the insulating layer, which reaches the top surface of the light-emitting elements.

A gap between adjacent first electrodes may be greater than a width of each of the first element electrodes of the light-emitting elements.

Because the light-emitting elements are not provided across adjacent first electrodes, it is possible to prevent short-circuiting between the first electrodes. Thus, it is possible to manufacture the display device with simple steps while reducing the positioning accuracy when arranging the light-emitting elements.

Metal wiring lines may be arranged in parallel with each other on at least one surface of the first electrodes and the second electrodes.

According to the configuration above, it is possible to reduce the resistance of the electrodes.

A light-shielding layer may be provided so as to cover the metal wiring lines from a display surface side.

According to the configuration above, it is possible to mitigate a decrease in display quality resulting from reflection of light by the metal wiring lines.

The first substrate and the second substrate may each include a film substrate, and the first substrate and the second substrate may be deformable.

According to the configuration above, it is possible to attain a flexible display.

A fluorescent layer may be provided further towards a display surface side than the light-emitting elements, and light emitted by the light-emitting elements may pass through the fluorescent layer to become visible light.

According to the configuration above, it is possible to convert light from the light-emitting element to visible light and emit this light.

Color filters provided further towards a display surface side than the light-emitting elements may be further included.

According to the configuration above, even if light from the light-emitting elements is of a single color, it is possible to attain color display and to provide a low cost display device.

The color filters may be provided on the second substrate, and a distance between the adjacent light-emitting elements may be three or more times a thickness of the second substrate and the color filters combined.

According to the configuration above, it is possible to dispose adjacent light-emitting element at a sufficient distance from each other. In this manner, light emitted from the light-emitting elements is guided inside the display device, and the amount of light that is not emitted outside from the display device can be reduced. In other words, light emitted by the light-emitting elements can efficiently contribute to display.

The light-emitting elements may be LED elements.

The LED elements may emit blue light or ultraviolet light.

According to the configuration above, it is possible to provide an inexpensive display device using inexpensive LED elements.

In a method of manufacturing a display device according to one aspect of the present invention the display device includes: a first substrate including a plurality of first electrodes; a second substrate including a plurality of second electrodes and disposed to face the first substrate; and light-emitting elements that emit light by a voltage being applied thereto, wherein the first electrodes and the second electrodes are arranged in stripe patterns such that the first electrodes extend in a direction differing from a direction in which the second electrodes extend, wherein the first electrodes each have an intersection that overlaps the second electrode in a plan view, wherein the light-emitting elements each include a first element electrode provided on bottom surfaces thereof, and a second element electrode provided on top surfaces thereof, and wherein the method includes: arranging a plurality of the light-emitting elements simultaneously on the first substrate such that at least respective portions of the light-emitting elements overlap the intersections in a plan view and the first electrodes are respectively connected electrically to the first element electrodes.

According to the configuration above, it is possible to arrange the light-emitting elements on the substrate without the need for high positional accuracy.

Also, by arranging the light-emitting elements at the intersecting regions of the electrodes, it is possible to arrange many light-emitting elements in a display surface of a certain area.

In this manner, it is possible to provide a manufacturing method by which it is possible to manufacture a display device having light-emitting elements at a high efficiency and low cost.

An insulating layer may be provided in an area between the first substrate and the second substrate, and the method may further include: disposing a non-cured insulating layer to cover the light-emitting elements arranged on the first substrate; and curing the insulating layer such that the insulating layer after being cured does not cover the first element electrodes and the second element electrodes.

According to the configuration above, it is possible to expose the second element electrodes and electrically connect them to the second electrodes. Also, by providing an insulating layer between the first substrate and the second substrate, it is possible to prevent short-circuiting between the first electrodes and the second electrodes.

The method may further include: curing the insulating layer such that the insulating layer after being cured reaches a surface of each of the light-emitting elements facing the second substrate.

The second element electrodes may protrude from a surface of each of the light-emitting elements facing the second substrate, and the method may further include: curing the insulating layer such that the insulating layer after being cured reaches a periphery of each of the second element electrodes.

According to the configuration above, it is possible to cover the surfaces of the light-emitting elements by the insulating layer. Thus, it is possible to prevent short-circuiting in the light-emitting element resulting from the conductor coming into contact with the surface of the light-emitting element. Also, it is possible to bond the second substrate to the first substrate and the light-emitting elements without the use of a second adhesive layer by using the insulating layer, which reaches the top surface of the light-emitting elements.

The insulating layer may be photocurable, and the method may further include: curing the insulating layer by radiating light from the first substrate side to the insulating layer.

According to the configuration above, it is possible for light to reach the surface of the light-emitting element facing the second substrate and irradiate the insulating layer. In this manner, it is possible to cure the insulating layer.

Each of the first electrodes may be provided with a first adhesive layer thereon, and the method may further include arranging a plurality of the light-emitting elements simultaneously on the first substrate such that the first electrodes are respectively connected electrically to the first element electrodes through the first adhesive layer.

According to the configuration above, it is possible to form a reliable electrical connection between the first element electrodes and the first electrodes.

A light-shielding member may be provided on the first substrate in an area other than the intersections, and the method may further include: curing the insulating layer by radiating light from the first substrate side to the insulating layer; and bonding the first adhesive layer to the first substrate in an area overlapping the light-shielding member in a plan view by removing the insulating layer that has not been cured due to light being blocked therefrom.

According to the configuration above, a stronger connection can be formed between the first substrate and the second substrate.

The first adhesive layer may be a positive resist, and the method may further include: disposing the first adhesive layer on the first electrodes; disposing the light-emitting elements on the first adhesive layer; and removing the first adhesive layer in portions not overlapping the light-emitting elements in a plan view by radiating light from the light-emitting element side towards the first adhesive layer.

According to the configuration above, by providing conductive members only in necessary locations and not in unnecessary locations, the possibility of a short-circuit can be decreased.

The method may further include: forming the first adhesive layer on the intersections.

According to the configuration above, by providing conductive members only in necessary locations and not in unnecessary locations, the possibility of a short-circuit can be decreased.

The plurality of light-emitting elements may be arranged simultaneously on the first substrate by bonding the first substrate to an element substrate formed by disposing the plurality of light-emitting elements on a first sheet.

According to the configuration above, it is possible to simultaneously arrange a plurality of light-emitting elements onto the first substrate by a simple method.

The method may further include: forming the plurality of light-emitting elements arranged in a matrix by cutting a light-emitting element wafer bonded onto the first sheet; and widening gaps between the plurality of light-emitting elements by stretching the first sheet.

According to the configuration above, it is possible to adjust the gap between the light-emitting elements by a simple method. As a result, when mounting the plurality of light-emitting elements simultaneously onto the first substrate, it is possible to electrically connect the first electrodes to the light-emitting elements.

The light-emitting elements may be sandwiched between the first sheet and a second sheet, and the first sheet and the second sheet may be stretched.

According to the configuration above, it is possible to protect the light-emitting elements and improve yield during the step of transferring the light-emitting elements.

The method may further include: arranging the second substrate such that the second electrodes are electrically connected to the second element electrodes.

Each of the second electrodes may be provided with a second adhesive layer thereon, and the method may further include: arranging the second substrate such that the second electrodes are electrically connected to the second element electrodes through the second adhesive layer.

A display device according to one aspect of the present invention includes: a first substrate having first electrodes; a second substrate having second electrodes and disposed to face the first substrate; and a plurality of light-emitting elements that are provided between the first electrodes and the second electrodes and emit light by having a voltage applied thereon, wherein the light-emitting elements each have the upper electrode (second element electrode) electrically connected to each of the second electrodes, the lower electrode (first element electrode) electrically connected to each of the first electrodes, and a light-emitting portion electrically connected to the upper electrode and the lower electrode, wherein the lower electrode, the light-emitting portion, and the upper electrode are stacked in that order, wherein the upper electrode has, on a surface facing the light-emitting portion, a contact portion in contact with the light-emitting portion and a non-contact portion not in contact with the light-emitting portion, and wherein, by providing the first insulating layer between the non-contact portion and the light-emitting portion, a distance between the second electrode and the lower electrode in a direction perpendicular to a surface of the first substrate is greater than a total thickness of the light-emitting portion and the upper electrode.

According to the configuration above, a sufficient distance can be ensured between the second electrode and the lower electrode. Thus, it is possible to reduce the risk of short-circuiting between the second electrode and the lower electrode.

In this manner, it is possible to provide a display device by which it is possible to accurately control light emitted by the light-emitting elements. Also, it is possible to provide a low cost display device having light-emitting elements.

The lower electrode and the first electrode may be electrically connected through an anisotropic conductive material, the second electrode and the upper electrode may be electrically connected through an anisotropic conductive material, the lower electrode may have, on a surface facing the light-emitting portion, an exposed portion that does not overlap the light-emitting portion in a plan view, and a second insulating layer may be provided on the exposed portion.

According to the configuration above, by interposing the anisotropic conductive material between the second electrode and the lower electrode, it is possible to prevent short-circuiting between the electrodes. In this manner, it is possible to provide a display device by which it is possible to accurately control light emitted by the light-emitting elements.

The anisotropic conductive material may be provided in an area between the first substrate and the second substrate, the anisotropic conductive material may include insulating spacers, and the spacers may be provided in positions not overlapping the light-emitting elements in a plan view.

According to the configuration above, a short-circuit between the first electrode and the second electrode can be prevented.

The contact portion may have gold electrodes, with the second electrode and the light-emitting portion being electrically connected at the contact portion through the gold electrodes.

According to the configuration above, it is possible to reduce the electrical resistance between the first electrode and the light-emitting portion, pass an electrical current efficiently through the light-emitting portion, and emit light.

In a method of manufacturing a display device according to one aspect of the present invention, the display device includes: a first substrate having first electrodes; a second substrate having second electrodes and disposed to face the first substrate; and a plurality of light-emitting elements that are provided between the first electrodes and the second electrodes and emit light by having a voltage applied thereon, the method including: adjusting gaps between the plurality of light-emitting elements by deforming a first film that is a stretchable film having the plurality of light-emitting elements disposed on a surface thereof; and providing the first film on the first substrate such that the light-emitting elements are electrically connected to the first electrodes.

According to the configuration above, it is possible to adjust the gap between the light-emitting elements and mount the light-emitting elements onto the first substrate using the first film. Thus, a step of transferring the light-emitting elements is not needed, and a transfer film for transfer is also not needed.

In this manner, it is possible to provide a method of manufacturing a display device by which it is possible to accurately control light emitted by the light-emitting elements. Also, it is possible to provide a manufacturing method by which it is possible to manufacture a low cost display device having light-emitting elements at a high efficiency and low cost.

The method may further include: providing the light-emitting elements on the second substrate through a second film such that the light-emitting elements are electrically connected to the second electrodes.

The method may further include: sandwiching the plurality of light-emitting elements between the first film and the second film by bonding together the first film and the second film; and fixing the first film to the first substrate and the second film to the second substrate by pressure.

The method may further include: adjusting the gaps between the plurality of light-emitting elements by deforming the first film and the second film with the plurality of light-emitting elements being sandwiched between the first film and the second film.

According to the configuration above, it is possible to adjust the gap between the light-emitting elements and mount the light-emitting elements onto the substrate while protecting the light-emitting elements.

The light-emitting element may have upper electrodes and lower electrodes, the upper electrodes and the lower electrodes may form surfaces of the light-emitting elements opposite to each other, and the method may further include: electrically connecting the upper electrodes to the second electrodes and electrically connecting the lower electrodes to the first electrodes.

According to the configuration above, by sandwiching the light-emitting element between the first electrode and the second electrode, it is possible to electrically connect the upper electrode to the first electrode and the lower electrode to the second electrode with ease.

At least one of the first film and the second film may include a plurality of conductive balls that are particles, and at least either of the upper electrodes and the lower electrodes may be electrically connected to the first electrodes through the conductive balls.

The method may further include: providing insulating spacers between the first film and the second film, and the spacers may be provided in positions not overlapping the light-emitting elements in a plan view.

The method may further include: dispersing the spacers on the first film having the plurality of light-emitting elements arranged on a surface thereof; and removing the spacers on the light-emitting elements by wind pressure.

According to the configuration above, a short-circuit between the first electrode and the second electrode can be prevented.

A conductor may be fixed onto a surface of at least either of the upper electrodes and the lower electrodes, and at least either of the upper electrodes and the lower electrodes may be electrically connected to at least either of the first electrodes and the second electrodes through the conductive balls.

According to the configuration above, it is possible to reliably connect electrically the electrodes on the light-emitting element respectively to the first electrode and the second electrode.

The surface of the conductor may be fluorine-coated.

According to the configuration above, the conductors provided on the electrodes of the light-emitting element penetrate the first film and are reliably connected respectively to the first electrode and the second electrode. As a result, it is possible to more reliably connect electrically the electrodes on the light-emitting element respectively to the first electrode and the second electrode.

The method may further include: fixing the first film and the second film between the first substrate and the second substrate by sandwiching the first film and the second film between the first substrate and the second substrate and applying pressure thereon.

The present invention is not limited to the embodiments described above, and various modifications can be made without departing from the scope of the claims. Therefore, embodiments obtained by appropriately combining the techniques disclosed in different embodiments are included in the technical scope of the present invention.

### INDUSTRIAL APPLICABILITY

The present invention can use used in a display device, a flexible display, a transparent display, or the like using light-emitting elements.

### DESCRIPTION OF REFERENCE CHARACTERS

6 dicing tape (first sheet)
10, 60 first substrate
12, 62 first electrode
13 first anisotropic conductive layer (first adhesive layer)
15 light-shielding member
16 metal electrode (metal wiring line)
17 light-shielding layer
20, 63 second substrate
22, 65 second electrode
23 second anisotropic conductive layer
30, 130, 130A LED element (light-emitting element)
31 first element electrode
33 second element electrode
40 insulating layer
50, 150 lower electrode (first element electrode)
60 light-emitting portion
70, 170 upper electrode (second element electrode)
80 transparent insulator (first insulating layer, second insulating layer)
90 anisotropic conductive material
91 conductive particle (conductive ball)
95 first anisotropic conductive film (first film)
96 second anisotropic conductive film (second film)
97 insulating resin film (first film, second film)
103 conductive protrusion (conductor)
110 insulating material layer (spacer)
111 glass spacer (spacer)
101 conductive resin (first adhesive layer)
102 positive conductive resin (first adhesive layer)
201, 301 conductive adhesive (first adhesive layer)
R-CF, G-CF, B-CF color filter

1. A display device, comprising:
a first substrate including a plurality of first electrodes;
a second substrate including a plurality of second electrodes disposed to face the first substrate; and
light-emitting elements that emit light by a voltage applied thereto,
wherein the first electrodes and the second electrodes are arranged in stripe patterns such that the first electrodes extend in a direction differing from a direction in which the second electrodes extend,
wherein the light-emitting elements are provided between the first substrate and the second substrate in intersecting regions, the intersecting regions being regions where the first electrodes and the second electrodes intersect in a plan view, and
wherein each of the light-emitting elements includes a first element electrode provided in a bottom surface of the light-emitting element and electrically connected to the first electrode thereunder, and a second element electrode provided in a top surface of the light-emitting element and electrically connected to the second electrode thereabove.

2. The display device according to claim 1,
wherein a first adhesive layer is formed on the respective first element electrodes,
wherein each of the light-emitting elements is fixed onto the first electrode through the first adhesive layer, and
wherein the first element electrode is electrically connected respectively to the first electrode through the first adhesive layer.

3. The display device according to claim 2, wherein the first electrodes each have an exposed portion not covered by the first adhesive layer.

4. The display device according to claim 3, wherein a width of the exposed portion is less than a width of the first element electrode.

5. The display device according to claim 2,
wherein the first substrate includes a transparent substrate,
wherein the first adhesive layer is provided on the transparent substrate so as to cover the first electrodes,
wherein the first adhesive layer electrically connects the first element electrodes to the first electrodes by being conductive in a direction perpendicular to a surface of the first substrate, and
wherein the first adhesive layer insulates adjacent said first electrodes from each other by not being conductive in a direction parallel to the surface of the first substrate.

6. The display device according to claim 2,
wherein a second adhesive layer is formed on the respective second element electrodes,
wherein each of the light-emitting elements is fixed onto the second electrodes through the second adhesive layer, and
wherein the second element electrodes are electrically connected respectively to the second electrodes through the second adhesive layer.

7. The display device according to claim 6, wherein the first adhesive layer is bonded to the second adhesive layer in at least a portion of an area between the first substrate and the second substrate other than the intersecting regions.

8. The display device according to claim 1, further comprising:
an insulating layer in an area between the first substrate and the second substrate.

9. The display device according to claim 8, wherein the first substrate and the second substrate are bonded to each other by the insulating layer.

10. The display device according to claim 9, wherein the insulating layer is disposed to reach a surface of each of the light-emitting elements that faces the second substrate.

11. The display device according to claim 9,
wherein the second element electrode protrudes upward at the top surface of the light-emitting element that faces the second substrate, and
wherein the insulating layer is disposed to reach a periphery of each of the second element electrodes.

12. The display device according to claim 1, wherein a gap between adjacent first electrodes is greater than a width of each of the first element electrodes of the light-emitting elements.

13. The display device according to claim 1, further comprising:
metal wiring lines arranged in parallel with each other on a surface of at least one of the first and second electrodes.

14. The display device according to claim 13, further comprising:
a light-shielding layer covering the metal wiring lines from a display surface side.

15. The display device according to claim 1,
wherein the first substrate and the second substrate each include a film substrate, and
wherein the first substrate and the second substrate are deformable.

16. The display device according to claim 1, further comprising:
a fluorescent layer provided further towards a display surface side than the light-emitting elements,
wherein light emitted by the light-emitting elements passes through the fluorescent layer to become visible light.

17. The display device according to claim 1, further comprising:
color filters provided further towards a display surface side than the light-emitting elements.

18. The display device according to claim 17,
wherein the color filters are provided on the second substrate, and
wherein a distance between adjacent said light-emitting elements is three or more times a thickness of the second substrate and the color filters combined.

19. The display device according to claim 1, wherein the light-emitting elements are light-emitting diodes.

20. The display device according to claim 19, wherein the light-emitting diodes emit blue light or ultraviolet light.

21. The display device according to claim 1,
wherein the light-emitting elements each have a light-emitting portion electrically connected to the corresponding second element electrode and the corresponding first element electrode,
wherein the first element electrode, the light-emitting portion, and the second element electrode are stacked in that order,
wherein the second element electrode has, on a surface facing the light-emitting portion, a contact portion in contact with the light-emitting portion and a non-contact portion not in contact with the light-emitting portion, and
wherein, a first insulating layer is disposed between the non-contact portion and the light-emitting portion such that a distance between the second electrode thereabove and the first element electrode in a direction perpendicular to a surface of the second substrate is greater than a total of a thickness of the light-emitting portion and a thickness of the second element electrode.

22. The display device according to claim 21,
wherein the first electrode and the first element electrode are electrically connected through an anisotropic conductive material,
wherein the second electrode and the second element electrode are electrically connected through the anisotropic conductive material,
wherein the first element electrode has, on a surface facing the light-emitting portion, an exposed portion that does not overlap the light-emitting portion in a plan view, and
wherein a second insulating layer is provided on the exposed portion.

23. The display device according to claim 22,
wherein the anisotropic conductive material is provided in an area between the first substrate and the second substrate,
wherein the anisotropic conductive material includes insulating spacers, and
wherein the spacers are provided in positions not overlapping the light-emitting elements in a plan view.

24. The display device according to claim 21,
wherein the contact portion of the second element electrode is made of gold, and
wherein the second electrode and the light-emitting portion are electrically connected through the gold electrode on the contact portion.

25. A method of manufacturing a display device, comprising:
preparing a first substrate having a plurality of first electrodes;
preparing a second substrate having a plurality of second electrodes; and
preparing a plurality of light-emitting elements that each emit light by a voltage applied thereto,
wherein the first electrodes and the second electrodes are respectively arranged in stripe patterns, and the first substrate and the second substrate are configured such that when coupled together, the first electrodes extend in a direction differing from a direction in which the second electrodes extend, and form intersections with the second electrode in a plan view,
wherein each of the light-emitting elements includes a first element electrode in a bottom surface thereof, and a second element electrode in a top surface thereof, and
wherein the method further comprises:
disposing the plurality of light-emitting elements at once on the first substrate such that the light-emitting elements respectively overlap said intersections in a plan view and such that the first electrodes are respectively connected electrically to the first element electrodes of the light-emitting elements.

26. The method of manufacturing a display device according to claim 25,
wherein the method further comprises:
depositing a curable insulating layer over the first substrate having the light-emitting elements thereon; and
curing the curable insulating layer such that the cured insulating layer does not cover the first element electrodes and the second element electrodes.

27. The method of manufacturing a display device according to claim 26, wherein in the step of curing, the curable insulating layer is cured such that the cured insulating layer reaches the top surface of each of the light-emitting elements.

28. The method of manufacturing the display device according to claim 26,
wherein the second element electrode protrudes upward at the top surface of the light-emitting element, and
wherein the step of curing is performed such that the cured insulating layer reaches a periphery of each of the second element electrodes.

29. The method of manufacturing a display device according to claim 28,
wherein the curable insulating layer is photocurable, and
wherein in the step of curing, the curable insulating layer is cured by radiating light from the first substrate side to the curable insulating layer.

30. The method of manufacturing a display device according to claim 26, further comprising: forming a first adhesive layer on the first electrodes,
wherein the step of disposing the plurality of light-emitting elements is performed such that the first electrodes are respectively connected electrically to the first element electrodes through the first adhesive layer.

31. The method of manufacturing a display device according to claim 30,
wherein a light-shielding member is provided on the first substrate in an area other than the intersections,
wherein the step of curing includes radiating light from the first substrate side to the curable insulating layer, and
wherein the method further includes removing the curable insulating layer that has not been cured due to light being blocked by the light-shielding member, and bonding the first adhesive layer to the second substrate in an area overlapping the light-shielding member in a plan view.

32. The method of manufacturing a display device according to claim 30,
wherein the first adhesive layer is a positive resist,
wherein the step of disposing the plurality of light-emitting elements includes disposing the light-emitting elements on the first adhesive layer, and
wherein the method further includes removing the first adhesive layer in portions not overlapping the light-emitting elements in a plan view by radiating light from the light-emitting element side towards the first adhesive layer.

33. The method of manufacturing a display device according to claim 30, wherein:
the first adhesive layer is formed on the intersections.

34. The method of manufacturing a display device according to claim 25, wherein the step of preparing the plurality of light-emitting elements includes forming an element sheet having the plurality of light-emitting elements formed thereon,
wherein the step of disposing the plurality of light-emitting elements includes attaching said element sheet to the first substrate.

35. The method of manufacturing a display device according to claim 34, wherein the step of preparing the plurality of light-emitting elements includes:
bonding a light-emitting element wafer having the plurality of light-emitting elements formed thereon to a first sheet;
thereafter, dicing the light-emitting element wafer that has been bonded to the first sheet into the plurality of separated light-emitting elements; and
stretching the first sheet having the plurality of separated light-emitting elements thereon to widen gaps between the separated light-emitting elements, thereby forming said element sheet having the plurality of light-emitting elements formed thereon.

36. The method of manufacturing a display device according to claim 35,
wherein the light-emitting elements are sandwiched between the first sheet and a second sheet, and
wherein the step of stretching the first sheet includes stretching the second sheet together with the first sheet.

37. The method of manufacturing a display device according to claim 25, further comprising:
disposing the second substrate such that the second electrodes are electrically connected to the second element electrodes.

38. The method of manufacturing a display device according to claim 37, further comprising forming
a second adhesive layer on the second electrodes, and
wherein the step of disposing the second substrate is performed
such that the second electrodes are electrically connected to the second element electrodes through the second adhesive layer.

39. The method of manufacturing a display device according to claim 25, wherein the step of preparing the plurality of light-emitting elements includes
adjusting gaps between the plurality of light-emitting elements by deforming a first film that is a stretchable film having the plurality of light-emitting elements disposed on a surface thereof, and
wherein the step of disposing the plurality of light-emitting elements includes providing the first film having the plurality of light-emitting element formed thereon on the first substrate such that the light-emitting elements are electrically connected to the first electrodes through the first film.

40. The method of manufacturing a display device according to claim 39, further comprising:
disposing the second substrate such that the second element electrodes of the light-emitting elements are electrically connected to the second electrodes through a second film.

41. The method of manufacturing a display device according to claim 40, wherein the step of preparing the plurality of light-emitting elements includes
sandwiching the plurality of light-emitting elements between the first film and the second film by bonding the second film to the first film having the light-emitting elements formed thereon, and
wherein the step of disposing the plurality of light-emitting elements includes fixing the first film to the first substrate and the second film to the second substrate by pressure.

42. The method of manufacturing a display device according to claim 41, wherein the step of adjusting the gaps is performed
by deforming the first film and the second film with the plurality of light-emitting elements being sandwiched between the first film and the second film.

43. The method of manufacturing a display device according to claim 41,
wherein the second element electrode and the first element electrode form surfaces of the light-emitting element opposite to each other.

44. The method of manufacturing a display device according to claim 43,
wherein at least one of the first film and the second film includes a plurality of conductive balls establishing electrical connection between the first element electrodes with the first electrodes or between the second element electrodes with the second electrodes.

45. The method of manufacturing a display device according to claim 44, further comprising:
providing insulating spacers between the first film and the second film,
wherein the spacers are provided in positions not overlapping the light-emitting elements in a plan view.

46. The method of manufacturing a display device according to claim 45, further comprising:
dispersing the spacers on the first film having the plurality of light-emitting elements arranged on a surface thereof; and
removing the spacers on the light-emitting elements by wind pressure.

47. The method of manufacturing a display device according to claim 43,
wherein a conductive member is fixed onto a surface of at least one of the second element electrode and the first element electrode, the conductive member making electric connection between the second element electrode and the second electrode or between the first element electrode and the first electrode.

48. The method of manufacturing a display device according to claim 47, wherein a surface of the conductor member is fluorine-coated.

49. The method of manufacturing a display device according to claim 41, wherein the step of disposing the plurality of light-emitting elements includes sandwiching the first film and the second film between the first substrate and the second substrate and applying pressure thereon, thereby fixing the first film and the second film to the first substrate and the second substrate, respectively.
